(19) United States
(12) Patent Application Publication
(10) Pub. No.: US 2018/0158974 A1
(43) Pub. Date: Jun. 7, 2018

(54) SOLAR CELL REAR SURFACE PROTECTIVE SHEET AND SOLAR CELL MODULE

(71) Applicant: FUJIFILM CORPORATION, Tokyo (JP)

(72) Inventors: Daisuke HIRAKI, Shizuoka (JP); Yu ISOBE, Shizuoka (JP); Takeshi HAMA, Shizuoka (JP); Shigehide ITOH, Shizuoka (JP)

(21) Appl. No.: 15/883,116

(22) Filed: Jan. 30, 2018

Related U.S. Application Data
(63) Continuation of application No. PCT/JP2016/074705, filed on Aug. 24, 2016.

(30) Foreign Application Priority Data
Aug. 25, 2015 (JP) 2015-166280

(51) Int. Cl. H01L 31/049; H01L 31/0224; H01L 31/0203

(52) U.S. Cl. CPC H01L 31/049; H01L 31/0203; H01L 31/022425

(57) ABSTRACT

Provided are: a solar cell rear surface protective sheet including a resin base material, a first colored layer which is disposed on one surface side of the resin base material, has an average transmittance of 20% or higher for infrared radiation with a wavelength of 750 nm to 2500 nm, and has a transmittance of 1% or lower for ultraviolet radiation with a wavelength of 325 nm, and a second colored layer which is disposed on the other surface side of the resin base material and of which each of an average transmittance and an average reflectivity for infrared radiation with a wavelength of 750 nm to 2500 nm is 10% or lower; and a solar cell module in which a first colored layer side of the solar cell rear surface protective sheet is disposed on the sealing material side sealing the solar cell element.

### CROSS-REFERENCE TO RELATED APPLICATIONS

This application is a continuation application of International Application No. PCT/JP2016/074705, filed Aug. 24, 2016, the disclosure of which is incorporated herein by reference in its entirety. Further, this application claims priority from Japanese Patent Application No. 2015-166280, filed Aug. 25, 2015, the disclosure of which is incorporated herein by reference in its entirety.

### BACKGROUND OF THE INVENTION

### 1. Field of the Invention

The present invention relates to a solar cell rear surface protective sheet and a solar cell module.

### 2. Description of the Related Art

A solar cell module which uses crystalline silicon, amorphous silicon, or the like as a solar cell element is generally produced using a lamination method or the like in which a transparent front substrate on which sunlight is incident, a cell side substrate in which the solar cell element (hereinafter, sometimes referred to as “cell”) as a photovoltaic element is sealed with a sealing material, and a rear surface protective sheet (so-called solar cell back sheet) are laminated in this order and are subjected to evacuation and thermal compression bonding. The solar cell module is placed in an environment exposed to sunlight and the wind and rain (for example, on the roof) for a long period of time, various functions such as durability in a wet heat environment are required for the solar cell rear surface protective sheet forming the solar cell module.

From the viewpoint of imparting various functions, a laminate in which functional layers are laminated on a polyester film is used as the solar cell rear surface protective sheet. Examples of representative functional layers include an adhesive layer to be adhered to the sealing material of the cell side substrate, a white layer for improving the power generation efficiency by enhancing the function of reflecting sunlight incident onto the module, a black layer for imparting designability, and a weather-resistant layer for imparting long-term durability.

For example, JP2013-161817A discloses a solar cell module back sheet including a polyester support and a colored layer disposed on at least one surface of the polyester support, in which the colored layer includes a binder composed of an organic polymer, carbon black, and metal oxide fine particles and includes a solar cell module polymer sheet satisfying Expression (1) below.

1≤W2/W1≤10 Expression (1)

(in Expression (1), W1 represents the content (unit: mass %) of the carbon black in the colored layer, and W2 represents the content (unit: mass %) of the metal oxide fine particles in the colored layer.)

In addition, for example, JP2012-216689A discloses a solar cell module rear surface protective sheet formed by laminating a plurality of layers including at least a transparent adhesion layer which is disposed at the outermost layer in the solar cell module rear surface protective sheet and transmits all light and a reflective layer that reflects near-infrared radiation at 750 nm or higher and 1500 nm or lower, in which at least one layer of adhesion layers formed between the plurality of layers is a black adhesive layer and the black adhesive layer is formed of a black adhesive including a base resin and a dark organic pigment and transmits near-infrared radiation with a wavelength of 750 nm or higher and 1500 nm or lower.

### SUMMARY OF THE INVENTION

The solar cell module back sheet disclosed in JP2013-161817A is excellent in designability and insulating properties due to the black color. However, there is a possibility that the polyester support may be deteriorated by ultraviolet radiation and a reduction in weather resistance may be caused.

In addition, the solar cell module rear surface protective sheet disclosed in JP2012-216689A is the solar cell module rear surface protective sheet having black outer appearance, has sufficient weather resistance and durability, and sufficiently contributes to an improvement in the power generation efficiency of a solar cell module. However, in a case where the solar cell module rear surface protective sheet disclosed in JP2012-216689A is applied to a solar cell module, a colored layer is disposed on a sealing material side and the reflective layer is disposed on the atmosphere side. Therefore, it is considered that the colored layer absorbs infrared radiation and generates heat, and the infrared radiation is reflected again by the reflective layer toward the cell side, which causes a decrease in the power generation efficiency due to the heat generation.

An object of an aspect of the present invention is to provide a solar cell rear surface protective sheet which has weather resistance, suppresses an increase in the temperature of a solar cell element, and thus contributes to the suppression of a decrease in power generation efficiency.

An object of another aspect of the present invention is to provide a solar cell module which suppresses a decrease in power generation efficiency for a long period of time.

Means for achieving the object includes the following aspects.

<1> A solar cell rear surface protective sheet comprising: a resin base material; a first colored layer which is disposed on one surface side of the resin base material, has an average transmittance of 20% or higher for infrared radiation with a wavelength of 750 nm to 2500 nm, and has a transmittance of 1% or lower for ultraviolet radiation with a wavelength of 325 nm; and a second colored layer which is disposed on the other surface side of the resin base material and of which each of an average transmittance and an average reflectivity for infrared radiation with a wavelength of 750 nm to 2500 nm is 10% or lower.

<2> The solar cell rear surface protective sheet described in <1>, in which the first colored layer includes a pigment, and a total volume fraction of the pigment in the first colored layer is 40 vol % or less.

<3> The solar cell rear surface protective sheet described in <1> or <2>, in which the first colored layer includes a white pigment and at least one kind of pigment selected from a quinacridone-based compound, a phthalocyanine-based compound, a dioxazine-based compound, and a perylene-based compound.

<4> The solar cell rear surface protective sheet described in any one of <1> to <3>, in which the second colored layer includes carbon black and a white pigment.

<5> The solar cell rear surface protective sheet described in any one of <1> to <4>, an L* value, an a* value, and a b* value on the first colored layer side respectively satisfy L*≤40, −3.0≤a*≤3.0, and −20.0 b*≤0.0, and the second colored layer is black.

<6> A solar cell module comprising: a solar cell element; a sealing material sealing the solar cell element; a transparent front substrate which is adhered to the sealing material on a light receiving surface side of the solar cell element and is disposed at an outermost surface; and a solar cell rear surface protective sheet in which a first colored layer side of the solar cell rear surface protective sheet described in any one of <1> to <5> is adhered to the sealing material on the opposite side to the light receiving surface side of the solar cell element.

According to an aspect of the present invention, the solar cell rear surface protective sheet which has weather resistance, suppresses an increase in the temperature of the solar cell element, and thus contributes to the suppression of a decrease in power generation efficiency is provided. According to another aspect of the present invention, the solar cell module which suppresses a decrease in power generation efficiency for a long period of time is provided.

### BRIEF DESCRIPTION OF THE DRAWINGS

FIG. 1 is a schematic configuration diagram illustrating an example of a solar cell rear surface protective sheet.

FIG. 2 is a schematic configuration diagram illustrating an example of a solar cell module.

### DESCRIPTION OF THE PREFERRED EMBODIMENTS

Hereinafter, a solar cell rear surface protective sheet (hereinafter, sometimes referred to as “solar cell back sheet”) and a solar cell module of this disclosure will be described in detail with reference to the drawings as appropriate. Constituent elements denoted by using the same reference numerals in each of the drawings mean the same constituent elements. However, the present invention is not limited to the following embodiments and can be embodied with appropriate modifications within the scope of the object of the present invention.

In the specification of the present application, “to” which represents a range means a range including numerical values described before and after “to” as a lower limit and an upper limit. In addition, in a case where a unit is attached only to the upper limit, it means that the lower limit value is also in the same unit.

[Solar Cell Rear Surface Protective Sheet]

The solar cell rear surface protective sheet has a resin base material, a first colored layer which is disposed on one surface side of the resin base material, has an average transmittance of 20% or higher for infrared radiation with a wavelength of 750 nm to 2500 nm (hereinafter, sometimes simply referred to as “infrared radiation”), and has a transmittance of 1% or lower for ultraviolet radiation with a wavelength of 325 nm, and a second colored layer which is disposed on the other surface side of the resin base material and of which each of the average transmittance and the average reflectivity for infrared radiation with a wavelength of 750 nm to 2500 nm is 10% or lower.

Here, the average infrared transmittance, the ultraviolet transmittance, and the average infrared reflectivity in this specification will be described.

—Average Infrared Transmittance—

Light of 750 nm to 2500 nm (infrared measurement) is caused to be incident on a measurement surface of the solar cell rear surface protective sheet by a spectrophotometer, and the infrared transmittance of the first colored layer or the second colored layer is measured. The transmittance is measured every 5 nm from 750 nm to 2500 nm, and the average transmittance is calculated by the arithmetic mean.

—Ultraviolet Transmittance—

Light of 300 nm to 400 nm (ultraviolet measurement) is caused to be incident on a measurement surface of the solar cell rear surface protective sheet by a spectrophotometer, and the ultraviolet transmittance of the first colored layer is measured. The transmittance for ultraviolet radiation of 325 nm is the transmittance at wavelength of 325 nm.

—Average Infrared Reflectivity—

Light of 750 nm to 2500 nm is caused to be incident on a measurement surface of the solar cell rear surface protective sheet by a spectrophotometer, and the infrared reflectivity of the second colored layer is measured. The transmittance is measured every 5 nm from 750 nm to 2500 nm, and the average reflectivity is calculated by the arithmetic mean.

In the case of measuring the average infrared transmittance, the ultraviolet transmittance, or the average infrared reflectivity of the first colored layer or the second colored layer as described above, the measurement is carried out in a state in which the colored layer as a measurement object is provided on one surface of the resin base material and the colored layer that is not the measurement object is not provided. Specifically, the measurement may be carried out in a state in which the first colored layer or the second colored layer is formed only one surface of the resin base material, or in a case where the first colored layer and the second colored layer are already respectively formed on one surface and the other surface of the resin base material, the measurement may be carried out after the colored layer that is not the measurement object is peeled off.

Since a solar cell module is installed outdoors for a long period of time and is exposed to sunlight and the wind and rain, long-term durability is required. Therefore, it is desirable that the solar cell rear surface protective sheet used as a rear surface protective material also has long-term durability.

In addition, in the solar cell module, an increase in the temperature of a solar cell element (cell) leads to a decrease in power generation efficiency. Therefore, it is desirable to suppress an increase in the temperature of the cell.

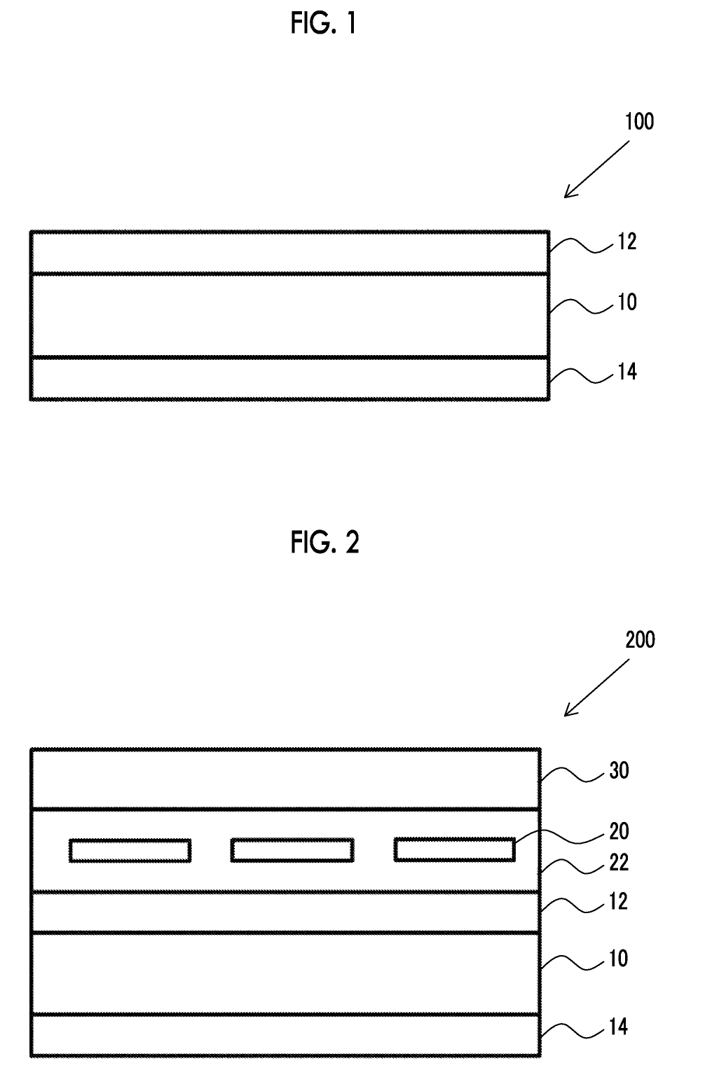

FIG. 1 schematically illustrates an example of a configuration of the solar cell rear surface protective sheet according to this embodiment. A solar cell rear surface protective sheet 100 illustrated in FIG. 1 has a resin base material 10, a first colored layer 12 which is disposed on one surface side of the resin base material 10, has an average transmittance of 20% or higher for infrared radiation with a wavelength of 750 nm to 2500 nm, and has a transmittance of 1% or lower for ultraviolet radiation with a wavelength of 325 nm, and a second colored layer 14 which is disposed on the other surface side of the resin base material and of which each of the average transmittance and the average reflectivity for infrared radiation with a wavelength of 750 nm to 2500 nm is 10% or lower. The solar cell rear surface protective sheet of the present invention has weather resistance and suppresses an increase in the temperature of the solar cell element, thereby contributing to the suppression of a decrease in power generation efficiency. The reason for this is considered as follows.

FIG. 2 schematically illustrates an example of a configuration of a solar cell module having the solar cell rear surface protective sheet of this embodiment. In a case where the solar cell module is manufactured using the solar cell rear surface protective sheet 100 of the present invention, as illustrated in FIG. 2, the first colored layer 12 side of the solar cell rear surface protective sheet 100 is adhered to a sealing material 22 that seals a solar cell element (cell) 20, and the second colored layer 14 side is disposed to be the outermost layer on the rear surface side of a solar cell module 200.

Since the first colored layer 12 positioned on the cell side of the solar cell module has an average transmittance of 20% or higher for infrared radiation with a wavelength of 750 nm to 2500 nm, most of infrared radiation that is incident from a front substrate 30 and is not absorbed but transmitted through a solar cell element 20 is transmitted through the first colored layer 12. Furthermore, although infrared radiation transmitted through the resin base material 10 reaches the second colored layer 14 positioned on the atmosphere side, each of the average transmittance and the average reflectivity of the second colored layer 14 for infrared radiation with a wavelength of 750 nm to 2500 nm is 10% or lower and thus the second colored layer 14 easily absorbs the infrared radiation. Therefore, most of the infrared radiation reaching the second colored layer 14 is absorbed by the second colored layer 14. In addition, infrared radiation incident from the atmosphere side is absorbed by the second colored layer 14 and is thus prevented from being incident on the cell side. Heat absorbed by the second colored layer 14 is dissipated to the atmosphere side and heat generation on the first colored layer 12 side of the solar cell rear surface protective sheet 100 is suppressed. Therefore, an increase in the temperature of the solar cell element 20 positioned in the vicinity of the first colored layer 12 is suppressed, and thus a decrease in the power generation efficiency is suppressed.

On the other hand, since the first colored layer 12 has a transmittance of 1% or lower for ultraviolet radiation with a wavelength of 325 nm, most of ultraviolet radiation that is light incident from the front substrate 30 and is not absorbed but transmitted through the solar cell element 20 is reflected by the first colored layer 12 of the solar cell rear surface protective sheet 100. Therefore, deterioration (yellowing and embrittlement) of the resin base material 10 due to the ultraviolet radiation is suppressed.

The solar cell module 200 provided with the solar cell rear surface protective sheet 100 of this embodiment has weather resistance for a long period of time and can exhibit high power generation efficiency.

Hereinafter, the configurations of the solar cell rear surface protective sheet and the solar cell module of this embodiment will be specifically described. In the following description, reference numerals may be omitted as appropriate.

<Resin Base Material>

The resin base material is a member that is to become a support of the solar cell rear surface protective sheet and is formed to include at least a resin.

As a material forming the resin base material, polyester, polycarbonate, polyamide, polymethyl methacrylate, and the like may be employed.

The resin base material is preferably a polyester film from the viewpoint of strength as a support, availability, handleability, manufacturing costs, and the like.

In addition, from the viewpoint of weather resistance, the resin base material is preferably a stretched film stretched in at least one direction, and more preferably a biaxially stretched film.

Therefore, the resin base material is particularly preferably a biaxially stretched polyester film. Hereinafter, a case of using a biaxially stretched polyester film as the resin base material will be described. However, the resin base material is not limited to the biaxially stretched polyester film.

The biaxially stretched polyester film is produced by stretching an un-stretched polyester film in a first direction (for example, film traveling direction (machine direction (MD))), and stretching the resultant along the film surface in a second direction (for example, film thickness direction (transverse direction (TD))) perpendicular to the first direction.

Examples of a polyester forming the polyester film include a linear saturated polyester synthesized from an aromatic dibasic acid or an ester-forming derivative thereof and a diol or an ester-forming derivative thereof. Specific examples of the linear saturated polyester include polyethylene terephthalate, polyethylene isophthalate, polybutylene terephthalate, poly(1,4-cyclohexylene dimethylene terephthalate), and polyethylene-2,6-naphthalate. Among these, in terms of the balance between mechanical properties and costs, polyethylene terephthalate, polyethylene-2,6-naphthalate, poly(1,4-cyclohexylene dimethylene terephthalate), and the like are particularly preferable.

The polyester may be a homopolymer or a copolymer. Furthermore, a small amount of another kind of resin such as polyimide may be blended in the polyester.

The kind of the polyester is not limited to the above-described polyester, and a well-known polyester may also be used. As the well-known polyester, a polyester may be synthesized by using a dicarboxylic acid component and a diol component. Otherwise, a commercially available polyester may also be used.

In a case where a polyester is synthesized, the polyester can be obtained by, for example, causing a (a) dicarboxylic acid component and a (b) diol component to undergo at least one of an esterification reaction or a transesterification reaction according to a well-known method.

Examples of the (a) dicarboxylic acid component include dicarboxylic acids or ester derivatives thereof including: aliphatic dicarboxylic acids such as malonic acid, succinic acid, glutaric acid, adipic acid, suberic acid, sebacic acid, dodecanedioic acid, dimer acid, eicosanedioic acid, pimelic acid, azelaic acid, methylmalonic acid, and ethylmalonic acid; alicyclic dicarboxylic acids such as adamantane dicarboxylic acid, norbornene dicarboxylic acid, cyclohexane dicarboxylic acid, and decalin dicarboxylic acid; and aromatic dicarboxylic acids such as terephthalic acid, isophthalic acid, phthalic acid, 1,4-naphthalene dicarboxylic acid, 1,5-naphthalene dicarboxylic acid, 2,6-naphthalene dicarboxylic acid, 1,8-naphthalene dicarboxylic acid, 4,4′-diphenyl dicarboxylic acid, 4,4′-diphenyl ether dicarboxylic acid, 5-sodium sulfoisophthalic acid, phenylindane dicarboxylic acid, anthracene dicarboxylic acid, phenanthrene dicarboxylic acid, and 9,9′-bis(4-carboxyphenyl) fluorensic acid.

Examples of the (b) diol component include diol compounds including: aliphatic diols such as ethylene glycol, 1,2-propanediol, 1,3-propanediol, 1,4-butanediol, 1,2-butanediol, and 1,3-butanediol; alicyclic diols such as cyclohexane dimethanol, spiroglycol, and isosorbide; and aromatic diols such as bisphenol A, 1,3-benzenedimethanol, 1,4-benzenedimethanol, and 9,9′-bis(4-hydroxyphenyl)fluorene.

As the (a) dicarboxylic acid component, at least one kind of the aromatic dicarboxylic acids is preferably used. More preferably, an aromatic dicarboxylic acid is included as a primary component in the dicarboxylic acid component. In addition, the “primary component” means that the proportion of the aromatic dicarboxylic acid in the dicarboxylic acid component is 80 mass % or more. A dicarboxylic acid component other than the aromatic dicarboxylic acid may also be included. As the dicarboxylic acid component, an ester derivative of an aromatic dicarboxylic acid or the like is used.

As the (b) diol component, at least one kind of the aliphatic diols is preferably used. As the aliphatic diol, ethylene glycol may be included, and ethylene glycol is preferably included as a primary component. In addition, the “primary component” means that the proportion of the ethylene glycol to the diol component is 80 mass % or more.

The amount of the aliphatic diol (for example, ethylene glycol) used is preferably in a range of 1.015 mol to 1.50 mol with respect to 1 mol of the aromatic dicarboxylic acid (for example, terephthalic acid) and, as necessary, an ester derivative thereof. The amount of the aliphatic diol used is more preferably in a range of 1.02 mol to 1.30 mol, and even more preferably in a range of 1.025 mol to 1.10 mol. In a case where the amount of the aliphatic diol used is in a range of 1.015 mol or more, the esterification reaction favorably proceeds, and in a case where the amount of the aliphatic diol used is in a range of 1.50 mol or less, for example, the generation of diethylene glycol as a byproduct due to the dimerization of ethylene glycol is suppressed, and characteristics such as melting point, glass transition temperature, crystallinity, heat resistance, hydrolysis resistance, and weather resistance can be favorably maintained.

In the esterification reaction or the transesterification reaction, a reaction catalyst which is hitherto well known may be used. As the reaction catalyst, alkali metal compounds, alkaline-earth metal compounds, zinc compounds, lead compounds, manganese compounds, cobalt compounds, aluminum compounds, antimony compounds, titanium compounds, and phosphorus compounds may be employed. Typically, in an arbitrary stage before the completion of a production method of the polyester, as a polymerization catalyst, an antimony compound, a germanium compound, or a titanium compound is preferably added. As such a method, for example, in a case where the germanium compound is exemplified, germanium compound powder is preferably added as it is.

For example, in the esterification reaction process, the aromatic dicarboxylic acid and the aliphatic diol are polymerized in the presence of a catalyst including a titanium compound. In this esterification reaction, as the titanium compound which serves as the catalyst, an organic chelate titanium complex having an organic acid as a ligand may be used, and the process may be provided with a procedure for adding at least the organic chelate titanium complex, a magnesium compound, and a pentavalent phosphoric acid ester with no aromatic ring as a substituent in this order.

Specifically, in the esterification reaction process, first, the aromatic dicarboxylic acid and the aliphatic diol are mixed with a catalyst including the organic chelate titanium complex, which is a titanium compound, before the addition of a phosphorus compound and a magnesium compound. The titanium compound such as the organic chelate titanium complex has an excellent catalytic activity for the esterification reaction and is thus capable of causing the esterification reaction to favorably proceed. In this case, the titanium compound may be added while the aromatic dicarboxylic acid component and the aliphatic diol component are mixed together, or the aliphatic diol component (or the aromatic dicarboxylic acid component) may be mixed after the aromatic dicarboxylic acid component (or the aliphatic diol component) and the titanium compound are mixed together. Otherwise, the aromatic dicarboxylic acid component, the aliphatic diol component, and the titanium compound may be mixed together at the same time. Mixing is not particularly limited to this method, and may be carried out by a well-known method.

In a case where the polyester is synthesized, the following compounds are preferably added.

As a pentavalent phosphorus compound, at least one pentavalent phosphoric acid ester with no aromatic ring as a substituent is used. For example, a phosphoric acid ester [(OR)₃—P═O; R is an alkyl group having 1 or 2 carbon atoms] having a lower alkyl group having 2 or less carbon atoms as a substituent may be employed. Specifically, trimethyl phosphate and triethyl phosphate are particularly preferable.

The amount of the phosphorus compound added is preferably in a range of 50 ppm to 90 ppm in terms of a phosphorus (P) element-equivalent value. The amount of the phosphorus compound is more preferably 60 ppm to 80 ppm, and even more preferably 60 ppm to 75 ppm.

By including a magnesium compound in the polyester, the electrostatic application property of the polyester improves.

Examples of the magnesium compound include magnesium salts such as magnesium oxide, magnesium hydroxide, magnesium alkoxide, magnesium acetate, and magnesium carbonate. Among these, from the viewpoint of solubility in ethylene glycol, magnesium acetate is the most preferable.

In order to impart a high electrostatic application property, the amount of the magnesium compound added is preferably 50 ppm or more in terms of a magnesium (Mg) element-equivalent value, and is more preferably in a range of 50 ppm to 100 ppm. The amount of the magnesium compound added is preferably in a range of 60 ppm to 90 ppm and even more preferably in a range of 70 ppm to 80 ppm in terms of imparting the electrostatic application property.

In the esterification reaction process, it is particularly preferable that the titanium compound as a catalyst component and the magnesium compound and the phosphorus compound as additives are added to be subjected to melt polymerization so that a value Z calculated from the following expression (i) satisfies the following relational expression (ii). Here, the P content refers to the amount of phosphorus derived from all phosphorus compounds including the pentavalent phosphoric acid ester with no aromatic ring, and the titanium (Ti) content refers to the amount of titanium derived from all Ti compounds including the organic chelate titanium complex. As described above, by selecting a combination of the magnesium compound and the phosphorus compound in a catalytic system including a titanium compound and controlling the addition timings and addition proportions thereof, a polyester with a slight yellow tint tone can be obtained while appropriately maintaining the catalytic activity of the titanium compound at a high level. Accordingly, heat resistance at a degree at which yellow coloration is less likely to occur even in a case where the polyester is exposed to a high temperature during a polymerization reaction or during subsequent film production (during melting) can be provided.

Z=5×(P content [ppm]/atomic weight of P)−2×(Mg content [ppm]/atomic weight of Mg)−4×(Ti content [ppm]/atomic weight of Ti) (i)

0≤Z≤5.0 (ii)

Since the phosphorus compound not only acts on titanium but also interacts with the magnesium compound, this serves as an index quantitatively representing the balance between the three.

Expression (i) represents the amount of phosphorus capable of acting on titanium by subtracting the amount of phosphorus that acts on magnesium from the total amount of phosphorus that can react. It can be said that, in a case where the value Z is a positive value, the amount of phosphorus that inhibits titanium is in an excessive state, and, conversely, in a case where the value Z is a negative value, the amount of phosphorus necessary to inhibit titanium is in an insufficient state. In the reaction, since a Ti atom, a Mg atom, and a P atom do not have equal valences, weighting is carried out by multiplying the mole numbers of the respective atoms in the expression by the valency numbers.

In addition, specific synthesis or the like is unnecessary for the synthesis of the polyester, and by using the titanium compound which is inexpensive and can be easily procured, and the phosphorus compound and the magnesium compound which are described above, a polyester having a reaction activity required for the reaction and excellent tone and coloration resistance against heat can be obtained.

In Expression (ii), from the viewpoint of further improving the tone and coloration resistance against heat in a state of maintaining the polymerization reactivity, it is preferable to satisfy 1.0≤Z≤4.0, and it is more preferable to satisfy 1.5≤Z≤3.0.

As a suitable aspect of the esterification reaction process, 1 ppm to 30 ppm of a chelate titanium complex having citric acid or citrate as a ligand may be added to the aromatic dicarboxylic acid and the aliphatic diol before the completion of the esterification reaction. Thereafter, it is preferable to add 60 ppm to 90 ppm (more preferably 70 ppm to 80 ppm) of a weakly acidic magnesium salt in the presence of the chelate titanium complex and after the above-described addition, further add 60 ppm to 80 ppm (more preferably 65 ppm to 75 ppm) of the pentavalent phosphoric acid ester with no aromatic ring as a substituent.

The esterification reaction process may be carried out while removing water or alcohols generated due to the reaction to be discharged to the outside of the system using a multi-stage apparatus including at least two reactors connected in series, under a condition in which ethylene glycol is refluxed.

The esterification reaction process may be carried out in a single stage or may be carried out in multiple separated stages.

In a case where the esterification reaction process is carried out in a single stage, the temperature of the esterification reaction is preferably 230° C. to 260° C. and more preferably 240° C. to 250° C.

In a case where the esterification reaction process is carried out in multiple separated stages, the temperature of the esterification reaction in a first reactor is preferably 230° C. to 260° C. and more preferably 240° C. to 250° C., and the pressure is preferably 1.0 kg/cm² to 5.0 kg/cm², and more preferably 2.0 kg/cm² to 3.0 kg/cm². The temperature of the esterification reaction in a second reactor is preferably 230° C. to 260° C., and more preferably 245° C. to 255° C., and the pressure is 0.5 kg/cm² to 5.0 kg/cm², and more preferably 1.0 kg/cm² to 3.0 kg/cm². Furthermore, in a case where the esterification reaction process is carried out in three or more separated stages, conditions for the esterification reaction in an intermediate stage are set to conditions between those in a first reactor and those in a final reactor.

Meanwhile, a polycondensation reaction of an esterification reaction product generated in the esterification reaction is caused so as to generate a polycondensate. The polycondensation reaction may be caused in a single stage or may be caused in multiple separated stages.

The esterification reaction product such as an oligomer generated in the esterification reaction is subsequently subjected to a polycondensation reaction. This polycondensation reaction can be suitably caused by supplying the esterification reaction product to a multi-stage polycondensation reactor.

For example, as for conditions of the polycondensation reaction in a case where the polycondensation reaction is caused in reactors in three stages, in the first reactor, the reaction temperature is 255° C. to 280° C. and more preferably 265° C. to 275° C. and the pressure is 100 to 10 torr (13.3×10⁻³ to 1.3×10⁻³ MPa) and more preferably 50 to 20 torr (6.67×10⁻³ to 2.67×10⁻³ MPa), in the second reactor, the reaction temperature is 265° C. to 285° C. and more preferably 270° C. to 280° C. and the pressure is 20 to 1 torr (2.67×10⁻³ to 1.33×10⁻⁴ MPa) and more preferably 10 to 3 torr (1.33×10⁻³ to 4.0×10⁻⁴ MPa), and in the third reactor in the final reactor, the reaction temperature is 270° C. to 290° C. and more preferably 275° C. to 285° C. and the pressure is 10 to 0.1 torr (1.33×10⁻³ MPa to 1.33×10⁻⁵ MPa) and more preferably 5 to 0.5 torr (6.67×10⁻⁴ to 6.67×10⁻⁵ MPa).

The polyester synthesized as described above may further include additives such as a light stabilizer, an antioxidant, an ultraviolet absorber, a flame retardant, a lubricant (that is, fine particles), a nucleating agent (crystallization agent), and a crystallization inhibitor.

During the synthesis of the polyester, after the polyester is polymerized by the esterification reaction, it is preferable to carry out solid-phase polymerization. By causing the polyester to undergo solid-phase polymerization, the moisture content of the polyester, the degree of crystallization, the acid value of the polyester, that is, the concentration of a terminal carboxyl group of the polyester, and the intrinsic viscosity can be controlled.

Particularly, it is preferable to carry out the solid-phase polymerization by setting the concentration of ethylene glycol (EG) gas at the initiation of the solid-phase polymerization to be higher than the concentration of the EG gas at the end of the solid-phase polymerization, in a range of 200 ppm to 1000 ppm. It is preferable to carry out the solid-phase polymerization by setting the concentration of the EG gas to be high in a range of more preferably 250 ppm to 800 ppm, and even more preferably 300 ppm to 700 ppm. In this case, AV (the concentration of terminal COOH) can be controlled by adding the EG at an average EG gas concentration (the average of the gas concentrations at the initiation and at the end of the solid-phase polymerization). That is, by adding EG to react with the terminal COOH, the AV can be reduced. The concentration of EG is preferably 100 ppm to 500 ppm, more preferably 150 ppm to 450 ppm, and even more preferably 200 ppm to 400 ppm.

In addition, the temperature of the solid-phase polymerization is preferably 180° C. to 230° C., more preferably 190° C. to 215° C., and even more preferably 195° C. to 209° C. In addition, the solid-phase polymerization time is preferably 10 hours to 40 hours, more preferably 14 hours to 35 hours, and even more preferably 18 hours to 30 hours.

Here, the polyester preferably has excellent hydrolysis resistance. Therefore, the content of the carboxyl group in the polyester is preferably 50 eq/t (here, ‘t’ represents ton) or less, more preferably 35 eq/t or less, and even more preferably 20 eq/t or less. In a case where the content of the carboxyl group is 50 eq/t or less, hydrolysis resistance can be maintained and a decrease in strength can be suppressed in a case of being exposed to moisture and heat for a period of time. The lower limit of the content of the carboxyl group is preferably 2 eq/t, and more preferably 3 eq/t in terms of maintaining the adhesiveness to a layer formed on the polyester (for example, the colored layers).

The content of the carboxyl group in the polyester can be adjusted by the kind of a polymerization catalyst, film production conditions (film production temperature and time), solid-phase polymerization, and additives (a terminal sealing agent and the like).

(Carbodiimide Compound and Ketenimine Compound)

The polyester film of which the raw material resin is polyester may include at least one of a carbodiimide compound or a ketenimine compound. The carbodiimide compound and the ketenimine compound may be used singly or in a combination of the two. Accordingly, deterioration of the polyester after thermal treatment is prevented, which is effective in maintaining favorable insulating properties even after thermal treatment.

The carbodiimide compound or the ketenimine compound is included preferably in a proportion of 0.1 mass % to 10 mass % in the polyester, more preferably in a proportion of 0.1 mass % to 4 mass %, and even more preferably in a proportion of 0.1 mass % to 2 mass %. In a case where the content of the carbodiimide compound or the ketenimine compound is set in the above-described range, the adhesiveness between the resin base material and an adjacent layer can be further enhanced. In addition, the heat resistance of the resin base material can be enhanced.

In addition, in a case where the carbodiimide compound and the ketenimine compound are used in combination, it is preferable that the sum of the contents of the two compounds is in the above-described range.

As the carbodiimide compound, a compound (including a polycarbodiimide compound) having one or more carbodiimide groups in a molecule may be employed. Specifically, examples of a monocarbodiimide compound include dicyclohexylcarbodiimide, diisopropylcarbodiimide, dimethylcarbodiimide, diisobutylcarbodiimide, dioctylcarbodiimide, t-butylisopropylcarbodiimide, diphenylcarbodiimide, di-t-butylcarbodiimide, di-β-naphthylcarbodiimide, and N,N′-di-2,6-diisopropylphenylcarbodiimide. Examples of the polycarbodiimide compound include polycarbodiimide compounds in which the lower limit of the degree of polymerization is typically 2 or higher and preferably 4 or higher, and the upper limit of the degree of polymerization is typically 40 or lower and preferably 30 or lower. Polycarbodiimide compounds produced using the methods described in the specification of U.S. Pat. No. 2,941,956 A, JP1972-33279B (JP-S47-33279B), J. Org. Chem. Vol. 28, p. 2069 to 2075 (1963), Chemical Review 1981, Vol. 81, Issue 4, p. 619 to 621, and the like may be employed.

Examples of an organic diisocyanate, which is a raw material for producing the polycarbodiimide compound, include aromatic diisocyanates, aliphatic diisocyanates, alicyclic diisocyanates, and mixtures thereof. Specific examples thereof include 1,5-naphthalene diisocyanate, 4,4′-diphenylmethane diisocyanate, 4,4′-diphenyldimethylmethane diisocyanate, 1,3-phenylene diisocyanate, 1,4-phenylene diisocyanate, 2,4-tolylene diisocyanate, 2,6-tolylene diisocyanate, a mixture of 2,4-tolylene diisocyanate and 2,6-tolylene diisocyanate, hexamethylene diisocyanate, cyclohexane-1,4-diisocyanate, xylylene diisocyanate, isophorone diisocyanate, 4,4′-dicyclohexylmethane diisocyanate, methyl cyclohexane diisocyanate, tetramethylxylylene diisocyanate, 2,6-diisopropylphenyl isocyanate, and 1,3,5-triisopropylbenzene-2,4-diisocyanate.

A specific polycarbodiimide compound that can be industrially procured is exemplified by CARBODILITE (registered trademark) HMV-8CA (manufactured by Nisshinbo Chemical Inc.), CARBODILITE (registered trademark) LA-1(manufactured by Nisshinbo Chemical Inc.), STABAXOL (registered trademark) P (manufactured by Rhein Chemie Corporation), STABAXOL (registered trademark) P100 (manufactured by Rhein Chemie Corporation), STABAXOL (registered trade mark) P400 (Rhein Chemie Corporation), and STABILIZER 9000 (manufactured by RASCHIG GmbH).

The carbodiimide compound may be used singly, but a mixture of a plurality of the compounds may also be used.

In addition, as the ketenimine compound, a ketenimine compound represented by General Formula (K-A) shown below is preferably used.

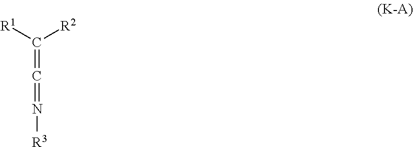

In General Formula (K-A), R¹ and R² each independently represent an alkyl group, an aryl group, an alkoxy group, an alkoxycarbonyl group, an aminocarbonyl group, an aryloxy group, an acyl group, or an aryloxycarbonyl group, and R³ represents an alkyl group or an aryl group.

Here, the molecular weight of a portion excluding the nitrogen atom and the substituent R³ bonded to the nitrogen atom in the ketenimine compound is preferably 320 or more. That is, in General Formula (K-A), the molecular weight of a R¹—C(═C)—R² group is preferably 320 or more. The molecular weight of the portion excluding the nitrogen atom and the substituent R³ bonded to the nitrogen atom in the ketenimine compound is preferably 320 or more, more preferably 500 to 1500, and even more preferably 600 to 1000. As described above, by causing the molecular weight of the portion excluding the nitrogen atom and the substituent R³ bonded to the nitrogen atom to be in the above-described range, the adhesiveness between the support and a layer that is in contact therewith can be increased. This is because, in a case where the portion excluding the nitrogen atom and the substituent R³ bonded to the nitrogen atom has a certain range of molecular weight, the polyester terminal which is bulky to a certain extent diffuses into the layer that is in contact with the support, and an anchorage effect is exhibited.

The biaxially stretched polyester film can be produced by stretching a sheet material formed using the above-mentioned raw material resin sequentially in two mutually orthogonal directions (the first direction and the second direction).

The thickness of the resin base material is not particularly limited, but from the viewpoint of ensuring strength as the support of the solar cell rear surface protective sheet, weather resistance, a voltage withstand property, handleability, and the like, preferably 30 μm or greater and 350 μm or smaller, more preferably 160 μm or greater and 300 μm or smaller, and even more preferably 180 μm or greater and 280 μm or smaller.

<First Colored Layer>

In the solar cell rear surface protective sheet of this embodiment, the first colored layer which has an average transmittance of 20% or higher for infrared radiation with a wavelength of 750 nm to 2500 nm, and has a transmittance of 1% or lower for ultraviolet radiation with a wavelength of 325 nm is disposed on one surface side of the resin base material (preferably a side to be adhered to the sealing material).

In the solar cell module produced by using the solar cell rear surface protective sheet of this embodiment, for example, in a case where the first colored layer side of the solar cell rear surface protective sheet is adhered to the sealing material on the solar cell element (cell) side, 20% or more of infrared radiation which is in the light that is incident from the transparent front substrate side and reaches the solar cell rear surface protective sheet through the solar cell element and has a wavelength of 750 nm to 2500 nm is transmitted such that heating due to absorption of the infrared radiation is suppressed. Accordingly, the power generation efficiency of the solar cell module can be improved. On the other hand, only 1% or less of ultraviolet radiation which is in the light reaching the solar cell rear surface protective sheet and has a wavelength of 325 nm is transmitted, that is, 99% or more of the ultraviolet radiation is reflected or absorbed. Therefore, the deterioration of the resin base material due to the ultraviolet radiation and embrittlement and yellow tinting thereof are suppressed.

The first colored layer may be directly disposed on the surface of the polyester film, or may be disposed on an undercoat layer disposed on the polyester film.

The first colored layer can be formed as a layer containing at least a binder and a colorant so as to have an average transmittance of 20% or higher for infrared radiation with a wavelength of 750 nm to 2500 nm and a transmittance of 1% or lower for ultraviolet radiation with a wavelength of 325 nm, and as necessary, may further include other components such as a crosslinking agent, a surfactant, and a filler.

From the viewpoint of suppressing heat generation due to the absorption of infrared radiation, the average transmittance of the first colored layer for infrared radiation with a wavelength of 750 nm to 2500 nm is preferably 25% or higher, and more preferably 30% or higher.

On the other hand, from the viewpoint of suppressing the deterioration of the resin base material due to ultraviolet radiation, the transmittance of the first colored layer for ultraviolet radiation with a wavelength of 325 nm is preferably 0.8% or lower, and more preferably 0.5% or lower.

(Binder)

Examples of the binder included in the first colored layer include an acrylic resin, a polyester-based resin, a polyurethane-based resin, and a polyolefin-based resin. Among these, an acrylic resin or a polyolefin-based resin is preferable.

(Colorant)

The average transmittance of the first colored layer for infrared radiation with a wavelength of 750 nm to 2500 nm and the transmittance thereof for ultraviolet radiation with a wavelength of 325 nm can be primarily adjusted by the kind and the content of the colorant included in the first colored layer.

The colorant included in the first colored layer is not particularly limited, and a well-known dye or pigment may be used. In addition, from the viewpoint of enhancing adhesiveness to a layer adjacent to the first colored layer, a pigment is preferable as the colorant included in the first colored layer.

For example, since a white colorant contributes to the reflection of ultraviolet radiation, it is preferable that the content of the white colorant is high in the first colored layer.

In the solar cell rear surface protective sheet, from the viewpoint of designability, the first colored layer may include colorants imparting colors other than black. Examples thereof include red and blue colorants.

On the other hand, although a black colorant can impart designability, the black colorant easily absorbs infrared radiation. Therefore, it is preferable that the content of the black colorant included in the first colored layer is suppressed to be low.

—White Colorant—

The first colored layer preferably includes a white pigment as a colorant that greatly contributes to the reflection of ultraviolet radiation. As the white pigment, inorganic pigments such as titanium oxide (TiO₂), barium sulfate, silicon dioxide, aluminum oxide, magnesium oxide, calcium carbonate, kaolin, talc, and colloidal silica, organic pigments such as hollow particles, and the like may be employed. Among these, titanium oxide is preferable.

As the crystalline form of titanium dioxide, there are a rutile form, an anatase form, and a brookite form. As the titanium oxide in this embodiment, a rutile form is preferable. The titanium dioxide may be subjected to a surface treatment as necessary using aluminum oxide (Al₂O₃), silicon dioxide (SiO₂), an alkanolamine compound, a silicon compound, or the like.

By including the white pigment in the first colored layer, the ultraviolet reflectivity of the first colored layer can be increased, and the deterioration of the resin base material can be suppressed.

The content of the white pigment in the case where the white pigment is used in the first colored layer depends on the kind thereof. However, from the viewpoint of increasing the ultraviolet reflectivity, the content thereof is preferably 5 mass % or more, more preferably 7 mass % or more, and even more preferably 10 mass % or more with respect to the total mass of the first colored layer.

On the other hand, from the viewpoint of increasing the adhesiveness between the first colored layer and another layer, although the content of the white pigment in the first colored layer depends on the kind thereof, the content thereof is preferably 60 mass % or less, more preferably 50 mass % or less, and even more preferably 40 mass % or less with respect to the total mass of the first colored layer.

The average particle diameter of the white pigment is preferably 0.03 μm to 0.8 μm, and more preferably 0.15 μm to 0.6 μm in terms of volume average particle diameter. In a case where the average particle diameter thereof is in the above-described range, the light reflection efficiency is excellent. The average particle diameter is a value measured using MICROTRAC MT3300EXII (manufactured by Nikkiso Co., Ltd.).

—Colorants other than Black and White Colorants—

As a red colorant, quinacridone-based compounds such as quinacridone red and quinacridone violet, dioxazine-based compounds such as dioxazine violet, perylene-based compounds such as perylene red and perylene violet, iron oxide, naphthol AS, and the like may be employed.

As a blue colorant, phthalocyanine-based compounds such as copper phthalocyanine, cobalt blue, and the like may be employed.

Since the red colorant and the blue colorant tend to slightly absorb infrared radiation, it is preferable that the content of these colorants in the first colored layer is suppressed to be low.

—Black Colorant—

As the black colorant used in the first colored layer, black pigments such as carbon black, titanium black, and black complex metal oxides may be employed.

Among these, it is preferable to use carbon black as the black pigment.

The carbon black is preferably carbon black particles having a particle diameter of 0.1 μm to 0.8 μm. It is preferable that the carbon black particles are dispersed in water together with a dispersant for use.

As the carbon black, a commercially available one may be used. Examples thereof include MF-5630 BLACK (manufactured by Dainichiseika Color & Chemicals Mfg. Co., Ltd.) and those described in paragraph “0035” of JP2009-132887A.

The black complex metal oxide is preferably a complex metal oxide including at least one selected from iron, manganese, cobalt, chromium, copper, or nickel, and more preferably a complex metal oxide including at least two selected from iron, manganese, cobalt, chromium, copper, and nickel. Among these, at least one pigment selected from pigments having color indexes Pigment Black (hereinafter, abbreviated to PBk) 26, PBk27, PBk28, and Pigment Blue (hereinafter, abbreviated to PBr) 34 is more particularly preferable.

Among the above-mentioned pigments, PBk26 is a complex oxide of iron, manganese, and copper, PBk27 is a complex oxide of iron, cobalt, and chromium, PBk-28 is a complex oxide of copper, chromium, and manganese, and PBr34 is a complex oxide of nickel and iron.

From the viewpoint of suppressing the ultraviolet transmittance to be low, imparting designability (for example, blue tint), and durability against ultraviolet radiation, as the colorant included in the first colored layer, the white pigment and at least one pigment selected from the quinacridone-based compounds, phthalocyanine-based compounds, the dioxazine-based compounds, and the perylene-based compounds are preferably included.

The total volume fraction of the pigments in the first colored layer is preferably 40 vol % or less. In a case where the total volume fraction of the pigments in the first colored layer is 40 vol % or less, the adhesiveness to an adjacent layer can be improved. From these viewpoints, the total volume fraction of the pigments in the first colored layer is more preferably 35 vol % or less, and even more preferably 30 vol % or less.

(Other Components)

The first colored layer may include other components such as a crosslinking agent, a surfactant, a filler, and an ultraviolet absorber as necessary. Among these, from the viewpoint of further improving the strength and durability of the first colored layer, it is preferable that a crosslinking agent is added to the resin and a crosslinking structure derived from the crosslinking agent is formed in the first colored layer.

—Crosslinking Agent—

As the crosslinking agent, an epoxy-based crosslinking agent, an isocyanate-based crosslinking agent, a melamine-based crosslinking agent, a carbodiimide-based crosslinking agent, an oxazoline-based crosslinking agent, and the like may be employed. Among the crosslinking agents, from the viewpoint of ensuring adhesiveness between the first colored layer and the polyester film, or between the first colored layer and the undercoat layer after exposure to moisture and heat for a period of time, an oxazoline-based crosslinking agent is particularly preferable.

Specific examples of the oxazoline-based crosslinking agent include
2-vinyl-2-oxazoline, 2-vinyl-4-methyl-2-oxazoline, 2-vinyl-5-methyl-2-oxazoline,
2-isopropenyl-2-oxazoline, 2-isopropenyl-4-methyl-2-oxazoline,
2-isopropenyl-5-ethyl-2-oxazoline, 2,2′-bis-(2-oxazoline), 2,2′-methylene-bis-(2-oxazoline),
2,2′-ethylene-bis-(2-oxazoline), 2,2′-trimethylene-bis-(2-oxazoline),
2,2′-tetramethylene-bis-(2-oxazoline), 2,2′-hexamethylene-bis-(2-oxazoline),
2,2′-octamethylene-bis-(2-oxazoline), 2,2′-ethylene-bis-(4,4′-dimethyl-2-oxazoline),
2,2′-p-phenylene-bis-(2-oxazoline), 2,2′-m-phenylene-bis-(2-oxazoline),
2,2′-m-phenylene-bis-(4,4′-dimethyl-2-oxazoline), bis-(2-oxazolinylcyclohexane)sulfide, and bis-(2-oxazolinylnorbornane)sulfide. Furthermore, (co)polymers of these compounds may also be preferably used.

As the oxazoline-based crosslinking agent, a commercially available product may be used. For example, EPOCROS (registered trademark) K2010E, K2020E, K2030E, WS500, and WS700 [all manufactured by Nippon Shokubai Co., Ltd.] may be used.

—Catalyst for Crosslinking Agent—

In the first colored layer, the crosslinking agent and a catalyst for the crosslinking agent may be used in combination.

In a case where the catalyst for the crosslinking agent is included, a crosslinking reaction between the binder (that is, resin) and the crosslinking agent is accelerated, and an improvement in the solvent resistance is achieved. In addition, as the crosslinking reaction favorably proceeds, the strength and dimensional stability of the second colored layer can be further improved. Particularly, in a case where a crosslinking agent having an oxazoline group (oxazoline-based crosslinking agent) is used as the crosslinking agent, a catalyst for the crosslinking agent may be used in combination.

As the catalyst for the crosslinking agent, onium compounds may be employed.

As the onium compounds, ammonium salts, sulfonium salts, oxonium salts, iodonium salts, phosphonium salts, nitronium salts, nitrosonium salts, diazonium salts, and the like may be suitably employed.

Specific examples of the onium compound include: ammonium salts such as ammonium monophosphate, ammonium diphosphate, ammonium chloride, ammonium sulfate, ammonium nitrate, ammonium p-toluenesulfonate, ammonium sulfamate, ammonium imidodisulfonate, tetrabutylammonium chloride, benzyltrimethyl ammonium chloride, triethylbenzyl ammonium chloride, tetrabutylammonium tetrafluoroborate, tetrabutyl ammonium hexafluorophosphate, tetrabutylammonium perchlorate, and tetrabutyl ammonium sulfate;

sulfonium salts such as trimethylsulfonium iodide, trimethylsulfonium tetrafluoroborate, diphenylmethylsulfonium tetrafluoroborate, benzyltetramethylenesulfonium tetrafluoroborate, 2-butenyltetramethylenesulfonium hexafluoroantimonate, and 3-methyl-2-butenyltetramethylenesulfonium hexafluoroantimonate;

oxonium salts such as trimethyloxonium tetrafluoroborate;

iodonium salts such as diphenyliodonium chloride and diphenyliodonium tetrafluoroborate;

phosphonium salts such as cyanomethyltributylphosphonium hexafluoroantimonate and ethoxycarbonylmethyltributylphosphonium tetrafluoroborate;

nitronium salts such as nitronium tetrafluoroborate;

nitrosonium salts such as nitrosonium tetrafluoroborate; and

diazonium salts such as 4-methoxybenzenediazonium chloride.

Among these, in terms of shortening the curing time, the onium compounds are more preferably the ammonium salts, the sulfonium salts, the iodonium salts, and the phosphonium salts, and more preferably the ammonium salts. From the viewpoint of safety, pH, and costs, phosphoric acid-based onium compounds and benzyl chloride-based onium compounds are preferable. Among the onium compounds, ammonium diphosphate is particularly preferable.

In the case of using the crosslinking agent in the first colored layer, the content of the crosslinking agent is preferably 0.5 parts by mass or more and 30 parts by mass or less, more preferably 3 parts by mass or more and less than 15 parts by mass with respect to 100 parts by mass of the resin component (that is, the binder) included in the first colored layer. In a case where the content of the crosslinking agent is 0.5 parts by mass or more, a favorable crosslinking effect is obtained while maintaining the strength and adhesiveness of the first colored layer. In a case where the content of the crosslinking agent is 30 mass % or less, the pot life of a coating liquid prepared for forming the first colored layer can be maintained for a long period of time. In a case where the content of the crosslinking agent is less than 15 mass %, the properties of a coating surface are improved.

—Surfactant—

As the surfactant, well-known surfactants such as anionic surfactants and nonionic surfactants may be employed.

In a case where the first colored layer includes the surfactant, the content of the surfactant is preferably 0.1 mg/m² to 10 mg/m² and more preferably 0.5 mg/m² to 3 mg/m². In a case where the content of the surfactant is 0.1 mg/m² or more, a favorable layer in which the generation of cissing of the coating liquid is suppressed is easily formed. In a case where the content of the surfactant is 10 mg/m² or less, adhesion between the first colored layer and the polyester film can be favorably carried out.

(Filler)

As the filler, a well-known filler such as colloidal silica may be used. The content of the filler is preferably 20 mass % or less, and more preferably 15 mass % or less with respect to the resin component (that is, the binder) of the first colored layer. In a case where the content of the filler is 20 mass % or less, the surface properties of the first colored layer can be more favorably maintained.

—Ultraviolet Absorber—

As the ultraviolet absorber, any of an organic ultraviolet absorber or an inorganic ultraviolet absorber may be used.

Examples of the organic ultraviolet absorber include a benzophenone-based ultraviolet absorber, a benzotriazole-based ultraviolet absorber, a cyanoacrylate-based ultraviolet absorber, a triazine-based ultraviolet absorber, a salicylic acid-based ultraviolet absorber, an oxalic acid anilide-based ultraviolet absorber, a malonic acid ester-based ultraviolet absorber, a benzoic acid-based ultraviolet absorber, a cinnamic acid-based ultraviolet absorber, and a dibenzoylmethane-based ultraviolet absorber.

Specifically, examples of the benzotriazole-based ultraviolet absorber include TINUVIN 326 (manufactured by BASF SE).

Examples of the triazine-based ultraviolet absorber include TINUVIN 400, TINUVIN 479, TINUVIN 400-DW, and TINUVIN 479-DW (all manufactured by BASF SE).

Examples of the oxalic acid anilide-based ultraviolet absorber include HOSTAVIN 3260 HP (manufactured by Clariant).

Examples of the malonic acid ester-based ultraviolet absorber include HOSTAVIN PR 25 (manufactured by Clariant).

Examples of the benzophenone-based ultraviolet absorber include CYASORB UV 531 (manufactured by Cytec Industries, Inc.).

A light stabilizer may be further included in addition to the ultraviolet absorber. As the light stabilizer, hindered phenol or hindered amine may be used.

Examples of the inorganic ultraviolet absorber include metal oxides such as titanium oxide, zinc oxide, and cerium oxide and carbon-based components such as carbon, fullerenes, carbon fibers, and carbon nanotubes.

The content of the ultraviolet absorber in the first colored layer depends on the kind of the ultraviolet absorber, but is preferably in a range of 0.2 g/m² to 20 g/m², and more preferably in a range of 0.3 g/m² to 10 g/m².

The thickness of the first colored layer is preferably in a range of 3 μm to 10 μm, and more preferably in a range of 4 μm to 8 μm. By setting the thickness of the first colored layer to be in the range of 3 μm to 10 μm, the balance between necessary transmittance, reflectivity, and adhesiveness is easily achieved.

<Easy-Adhesion Layer>

In the solar cell rear surface protective sheet, an easy-adhesion layer may be disposed on the first colored layer side of the resin base material.

The easy-adhesion layer is a layer disposed to enhance the adhesiveness of the solar cell rear surface protective sheet to the cell side substrate (particularly an ethylene vinyl acetate copolymer, hereinafter, sometimes referred to as “EVA”) provided with a solar cell in a case where the solar cell module is produced. Hereinafter, an easy-adhesion layer disposed by being brought into contact with the cell side substrate on which the cell is sealed with EVA as the sealing material is referred to as an “EVA side easy-adhesion layer”.

The EVA side easy-adhesion layer can be formed by providing an undercoat layer disposed between the resin base material and the first colored layer and an overcoat layer further disposed on the first colored layer.

In addition, the undercoat layer on the first colored layer side may employ the same configuration as an undercoat layer on the second colored layer side, which will be described later. In a case of forming undercoat layers on both surfaces of the resin base material, undercoat layers having the same configuration may be provided on both surfaces, or undercoat layers having different configurations may be provided.

<Overcoat Layer>

The solar cell rear surface protective sheet may further have an overcoat layer on the first colored layer on the resin base material. The overcoat layer includes at least a binder, and may use a crosslinking agent and other additives as necessary.

As the binder included in the overcoat layer, the same binder as the binder that can be used in the first colored layer is preferably used.

The crosslinking agent included in the overcoat layer is the same as the crosslinking agent that can be used in the first colored layer.

The content of the crosslinking agent in a coating liquid for forming the overcoat layer is preferably from 5 mass % or more and 40 mass % or less, and more preferably 10 mass % or more and 30 mass % or less with respect to the binder in the overcoat layer. In a case where the content of the crosslinking agent is 5 mass % or more, a polymer layer (overcoat layer) which has excellent crosslinking effect while maintaining strength and adhesiveness is obtained. In a case where the content of the crosslinking agent is 40 mass % or less, the pot life of the coating liquid prepared for forming the overcoat layer can be maintained for a long period of time.

As other additives than the crosslinking agent included in the overcoat layer, additives similar to the other additives described above regarding the first colored layer may be suitably used, and the amounts of the other additives added are also the same as those described regarding the first colored layer.

The thickness of the overcoat layer is preferably in a range of 0.1 μm to 5.0 μm, and more preferably in a range of 0.2 μm to 3.5 μm. By setting the thickness of the overcoat layer to be in the range of 0.1 μm to 5.0 μm, the adhesiveness to the sealing material disposed on the cell side substrate used for the production of the solar cell module can be strengthened.

<Second Colored Layer>

The second colored layer is a layer which is disposed on the other surface side of the resin base material, that is, on the opposite side to the first colored layer, each of the average transmittance and the average reflectivity thereof for infrared radiation with a wavelength of 750 nm to 2500 nm is 10% or lower. In the solar cell module to which the solar cell rear surface protective sheet of this embodiment is applied, most of infrared radiation that reaches the second colored layer through the first colored layer, the sealing material, the resin base material, and the like is absorbed by the second colored layer. In addition, infrared radiation incident from the rear surface side (atmosphere side) is absorbed by the second colored layer such that incidence thereof to the cell side is suppressed. In addition, since heat absorbed by the second colored layer is dissipated to the atmosphere side, an increase in the temperature of the solar cell element positioned in the vicinity of the first colored layer is suppressed.

The second colored layer includes at least a binder and a colorant and may further include other components such as a crosslinking agent, a surfactant, a filler, and an ultraviolet absorber as necessary.

(Binder)

As the binder included in the second colored layer, an acrylic resin, a polyester-based resin, a polyurethane-based resin, a polyolefin-based resin, and the like may be employed. Among these, from the viewpoint of long-term weather resistance, an acrylic resin is preferable.

—Acrylic Resin—

Examples of the acrylic resin include polymers including polymethyl methacrylate, polyethyl acrylate, or the like, and from the viewpoint of improving weather resistance against sunlight, the wind and rain, and the like, a silicone/acrylic composite resin composed of silicone and acrylate, an acrylic/fluorine composite resin composed of acrylate and a fluorine compound are preferable.

As the acrylic resin, a commercially available product which is released may be used. Examples thereof include AS-563A (manufactured by Daicel FineChem Ltd.), JURYMER (registered trademark) ET-410 and SEK-301 (both manufactured by Toagosei Co., Ltd.), and BONRON PS-001 and BONRON PS-002 (both manufactured by Mitsui chemicals, Inc.)

In addition, examples of the silicone/acrylic composite resin include CERANATE (registered trademark) WSA1060 and WSA1070 (both manufactured by DIC Corporation), and H7620, H7630, and H7650 (all manufactured by Asahi Kasei Corporation). Examples of the acrylic/fluorine composite resin include OBBLIGATO (registered trademark) SW0011F (manufactured by AGC Coat-Tech Co., Ltd.), SIFCLEAR F101, F102 (manufactured by JSR Corporation), and KYNAR AQUATEC ARC and FMA-12 (both manufactured by Arkema KK).

The silicone/acrylic composite resin is a polymer having a (poly)siloxane structure and an acrylic structure in a molecular chain. By including the silicone/acrylic composite resin, the second colored layer has excellent adhesiveness to an adjacent material such as the polyester film of the solar cell rear surface protective sheet and excellent durability in a wet heat environment.

The silicone/acrylic composite resin is not particularly limited as long as the silicone/acrylic composite resin has a (poly)siloxane structure and an acrylic structure in a molecular chain, and may be any of a homopolymer of a compound having a (poly)siloxane structural unit and an acrylic structure or a copolymer including a (poly)siloxane structural unit and an acrylic structural unit.

The silicone/acrylic composite resin preferably has a siloxane structural unit represented by General Formula (1) below as the (poly)siloxane structure.

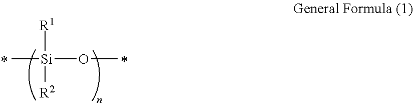

In General Formula (1), R¹ and R² each independently represent a hydrogen atom, a halogen atom, or a monovalent organic group. Here, R¹ and R² may be the same or different from each other, and a plurality of R¹'s or R²'s may be the same or different from each other. n represents an integer of 1 or higher.

A partial structure of “—(Si(R¹)(R²)—O)ₙ—”, which is the siloxane structural unit in the silicone resin, is a siloxane segment capable of forming a variety of (poly)siloxane structures having a linear, branched, or cyclic structure.

In a case where R¹ and R² represent a halogen atom, as the halogen atom, a fluorine atom, a chlorine atom, an iodine atom, and the like may be employed.

In a case where R¹ and R² represent a monovalent organic group, the monovalent organic group may be any group capable of forming a covalent bond to a Si atom. Examples thereof include an alkyl group (for example, a methyl group or an ethyl group), an aryl group (for example, a phenyl group), an aralkyl group (for example, a benzyl group, phenyl ethyl, or the like), an alkoxy group (for example, a methoxy group, an ethoxy group, or a propoxy group), an aryloxy group (for example, a phenoxy group), a mercapto group, an amino group (for example, an amino group or a diethylamino group), and an amide group. These organic groups may be unsubstituted groups or may further have a substituent.

n is preferably 1 to 5000 and more preferably 1 to 1000.

Among these, in terms of adhesiveness to an adjacent material such as the polyester film and durability in a wet heat environment, it is preferable that R¹ and R² are each independently a hydrogen atom, a chlorine atom, a bromine atom, an unsubstituted or substituted alkyl group having 1 to 4 carbon atoms (particularly, a methyl group or an ethyl group), an unsubstituted or substituted phenyl group, an unsubstituted or substituted alkoxy group, a mercapto group, an unsubstituted amino group, or an amide group. In terms of durability in a wet heat environment, it is more preferable that R¹ and R² are an unsubstituted or substituted alkoxy group (preferably an alkoxy group having 1 to 4 carbon atoms).

The proportion of a portion of “—(Si(R¹) (R²)—O)ₙ—” (the (poly)siloxane structural unit represented by General Formula (1)) in the resin is preferably 15 mass % to 85 mass % of the total mass of the resin. Particularly, from the viewpoint of improving the surface strength of the polyester film, preventing the generation of scratches caused by scratching, abrasion, or the like, and further improving adhesiveness to an adjacent material such as the polyester film and durability in a wet heat environment, the proportion of the (poly)siloxane structural unit is more preferably in a range of 20 mass % to 80 mass %. In a case where the proportion of the (poly)siloxane structural unit is 15 mass % or higher, the surface strength of the polyester film is improved, the generation of scratches caused by scratching, abrasion, collisions with flying pebbles, or the like is prevented, and excellent adhesiveness to an adjacent material such as the polyester film included in the resin base material is achieved. The prevention of the generation of scratches improves weather resistance, and peeling resistance which is likely to deteriorate due to heat or moisture, shape stability, and durability during exposure to a wet heat environment can be effectively enhanced. In addition, in a case where the proportion of the (poly)siloxane structural unit is 85 mass % or lower, a liquid can be stably maintained.

In the present invention, in a case where the acrylic resin is a copolymer having a (poly)siloxane structural unit and an acrylic structural unit, it is preferable that the (poly)siloxane structural unit represented by General Formula (1) and the acrylic structural unit are included respectively in a proportion of 15 mass % to 85 mass % by mass and in a proportion of 85 mass % to 15 mass % in the molecular chain. In a case where such a copolymer is included, the film hardness of the polyester film is improved, the generation of scratches caused by scratching, abrasion, or the like is prevented, adhesiveness to the polyester film included in the resin base material, that is, peeling resistance which is likely to deteriorate due to heat and moisture, shape stability, and durability in a wet heat environment can be significantly improved compared to the related art.

The copolymer is preferably a block copolymer which has the (poly)siloxane structural unit represented by General Formula (1), the acrylic structural unit, and a non-siloxane-based structural unit in certain cases, which are formed through copolymerization of a siloxane compound (including polysiloxane), an acrylic monomer, and a compound selected from a non-siloxane-based monomer (excluding an acrylic monomer) and a non-siloxane-based polymer in certain cases.

In this case, as the siloxane compound, and the acrylic monomer, the non-siloxane-based monomer, and the non-siloxane-based polymer to be copolymerized therewith, only one kind may be singly used, or two or more kinds may be used.

The non-siloxane-based structural unit copolymerized with the (poly)siloxane structural unit (derived from the acrylic monomer, the non-siloxane-based monomer, and the non-siloxane-based polymer) preferably has a polymer segment derived from an acrylic polymer. With the polymer segment derived from the acrylic polymer, in addition to ease of preparation, excellent hydrolysis resistance and excellent adhesiveness to the polyester film are achieved.

As a polymer forming the non-siloxane-based structural unit, one kind of an acrylic structural unit may be singly used, or two or more kinds of an acrylic structural unit may be used in combination.

In the second colored layer, one kind of the acrylic resin may be singly used, or the acrylic resin may also be used in combination with another resin. In a case of a combination with another resin, the content of the acrylic resin such as a composite resin including a (poly)siloxane structure is preferably 30 mass % or more, and more preferably 60 mass % or more with respect to the total resin amount. In a case where the content of the acrylic resin is 30 mass % or more, more favorable adhesion to the polyester film and excellent durability in a wet heat environment are achieved.

The molecular weight of the resin is preferably 5,000 to 100,000, and more preferably 10,000 to 50,000.

For the preparation of the resin having the (poly)siloxane structural unit, methods such as (i) a method in which a precursor polymer and polysiloxane having the structural unit represented by General Formula (1) are caused to react with each other or (ii) a method in which a silane compound having the structural unit represented by General Formula (1) in which at least one of R¹ or R² is a hydrolyzable group undergoes hydrolytic condensation in the presence of the precursor polymer may be used.

A variety of silane compounds may be employed as the silane compound used in the (ii) method, and an alkoxysilane compound is particularly preferable.

In a case where the resin is prepared using the (i) method, for example, the resin can be prepared by adding water and a catalyst as necessary to a mixture of the precursor polymer and polysiloxane and causing a reaction in the mixture at a temperature of about 20° C. to 150° C. for about 30 minutes to 30 hours (preferably at 50° C. to 130° C. for 1 hour to 20 hours). As the catalyst, a variety of silanol condensation catalysts such as an acidic compound, a basic compound, and a metal-containing compound may be added.

In addition, in a case where the resin is prepared using the (ii) method, for example, the resin can be prepared by adding water and a silanol condensation catalyst to a mixture of the precursor polymer and an alkoxysilane compound and causing hydrolytic condensation at a temperature of about 20° C. to 150° C. for about 30 minutes to 30 hours (preferably at 50° C. to 130° C. for 1 hour to 20 hours).

As the acrylic resin having a (poly)siloxane structure, a commercially available product which is released may be used. For example, CERANATE series (for example, CERANATE (registered trademark) WSA1070 and CERANATE WSA1060) manufactured by DIC Corporation, H7600 series (H7650, H7630, H7620, and the like) manufactured by Asahi Kasei Corporation, and an inorganic acrylic composite emulsion manufactured by JSR Corporation may be used.

The acrylic/fluorine composite resin is a polymer having a repeating unit represented by —(CFX¹—CX²X³)— and an acrylic repeating unit. In the formula, X¹, X², and X³ each independently represent a hydrogen atom, a fluorine atom, a chlorine atom, or a fluoroalkyl group having 1 to 3 carbon atoms.

Specific examples of the acrylic/fluorine composite resin include OBBLIGATO (registered trademark) SW0011F (manufactured by AGC Coat-Tech Co., Ltd.), SIFCLEAR F101 and SIFCLEAR F102 (manufactured by JSR Corporation), and KYNAR AQUATEC ARC and FMA-12 (both manufactured by Arkema KK).

The acrylic resin may be used by dissolving the acrylic resin in an organic solvent, or may be used by dispersing particles in water. The latter is preferable in terms of low environmental load.

Water dispersions of the acrylic resin are described in, for example, JP2003-231722A, JP2002-20409A, and JP1997-194538A (JP-H09-194538A), and the polymers described therein can be applied to the present invention.

The content of the acrylic resin in the second colored layer is preferably in a range of 0.5 g/m² to 20.0 g/m², and more preferably in a range of 8.0 g/m² to 20.0 g/m² from the viewpoint of improving the adhesion of the second colored layer to the resin base material.

Among these, the second colored layer preferably has a form in which, as the polymer (binder), CERANATE series manufactured by DIC Corporation or an inorganic acrylic composite emulsion manufactured by JSR Corporation is used.

As the resin of the second colored layer, one kind of acrylic resin may be used singly, or two or more kinds thereof may be used in combination.

A resin other than the acrylic resin, such as a fluororesin, polyester, polyurethane, polyolefin, and a silicone resin may be used in combination in a range of 50 mass % or less of the total resin. In a case where the content of the resin other than the acrylic resin is 50 mass % or less with respect to the resin component (binder) in the second colored layer, an effect of improving weather resistance is obtained.

(Colorant)

The colorant included in the second colored layer is not particularly limited as long as each of the average transmittance and the average reflectivity of the second colored layer for infrared radiation with a wavelength of 750 nm to 2500 nm is 10% or lower, and a well-known dye, a well-known pigment, and the like may be used. For example, from the viewpoint of absorbing infrared radiation to decrease the average transmittance for the infrared radiation, it is preferable that a large amount of a black colorant is included. From the viewpoint of absorbing ultraviolet radiation, designability, and the like, the second colored layer may include a white colorant.

From the viewpoint of further absorbing infrared radiation and dissipating heat by the second colored layer, each of the average transmittance and the average reflectivity of the second colored layer for infrared radiation with a wavelength of 750 nm to 2500 nm is preferably 9% or lower, and more preferably 8% or lower.

—Black Colorant—

As the black colorant used in the second colored layer, the same black colorant as that described regarding the first colored layer can be suitably used. Among these, from the viewpoint of absorbing infrared radiation in a small amount of the black colorant, carbon black is preferably used as the black pigment.

Although the content of the black colorant in the second colored layer depends on the kind thereof, the content thereof is preferably 5 mass % or more from the viewpoint of absorbing infrared radiation and decreasing the average transmittance for the infrared radiation, more preferably 5.5 mass % or more, and even more preferably 6 mass % or more with respect to the total mass of the second colored layer.

On the other hand, from the viewpoint of enhancing the adhesiveness of the second colored layer to another layer, although the content of the black pigment in the second colored layer depends on the kind thereof, the content thereof is preferably 50 mass % or less, more preferably 30 mass % or less, and even more preferably 20 mass % or less with respect to the total mass of the first colored layer.

—White Colorant—

As the white colorant used in the second colored layer, the same white colorant as that described regarding the first colored layer can be suitably used.

Although the content of the white colorant in the second colored layer depends on the kind thereof, the content thereof is preferably 5 mass % or more from the viewpoint ultraviolet reflectivity for protection of the resin base material, more preferably 8 mass % or more, and even more preferably 10 mass % or more with respect to the total mass of the second colored layer.

On the other hand, from the viewpoint of enhancing the adhesiveness of the second colored layer to another layer, the content of the white pigment in the second colored layer is preferably 80 mass % or less, more preferably 65 mass % or less, and even more preferably 50 mass % or less with respect to the total mass of the second colored layer.

From the viewpoint of causing each of the average transmittance and the average reflectivity for infrared radiation with a wavelength of 750 nm to 2500 nm to be 10% or lower and imparting designability, the second colored layer preferably includes carbon black and the white pigment. As the white pigment, inorganic pigments such as titanium oxide (TiO₂), barium sulfate, silicon dioxide, aluminum oxide, magnesium oxide, calcium carbonate, kaolin, talc, and colloidal silica may be suitably employed, and titanium oxide is more preferable.

(Other Components)

The second colored layer may include other components such as a crosslinking agent, a surfactant, a filler, and an ultraviolet absorber as necessary. Among these, from the viewpoint of further improving the strength and durability of the second colored layer, it is preferable that a crosslinking agent is added to the resin and a crosslinking structure derived from the crosslinking agent is formed in the second colored layer.

The crosslinking agent included in the second colored layer is the same as the crosslinking agent usable in the first colored layer.

The content of the crosslinking agent in the second colored layer is preferably 5 mass % or more and 40 mass % or less, and more preferably 10 mass % or more and 30 mass % or less with respect to the binder in the second colored layer. In a case where the content of the crosslinking agent is 5 mass % or more, a second colored layer which has excellent crosslinking effect while maintaining strength and adhesiveness is obtained. In a case where the content of the crosslinking agent is 40 mass % or less, the pot life of a coating liquid prepared for forming the second colored layer can be maintained for a long period of time.

As other additives than those described above included in the second colored layer, additives similar to those described above regarding the first colored layer may be suitably used, and the amounts of the other additives added are the same as those described regarding the first colored layer.

The thickness of the second colored layer is not particularly limited, and is preferably 3 μm or greater, and more preferably 5 μm or greater. In a case where the thickness of the second colored layer is 3 μm or greater, the solvent resistance of the second colored layer can be maintained more favorably, and in a case where the thickness of the second colored layer is 5 μm or greater, the solvent resistance of the second colored layer can be further improved.

On the other hand, the thickness of the second colored layer is preferably 50 μm or smaller, and more preferably 40 μm or smaller. In a case where the thickness of the second colored layer is 50 μm or smaller, the surface properties of the second colored layer can be maintained favorably, and in a case where the thickness of the second colored layer is 40 μm or smaller, the cracking resistance of the second colored layer against bending stress can be further improved.

<Undercoat Layer>

In the solar cell rear surface protective sheet, an undercoat layer may be disposed between the resin base material and the second colored layer.

As the undercoat layer on the second colored layer side, for example, a coating layer (hereinafter, sometimes referred to as “so-called inline coating layer”) which includes an acrylic resin and is formed by applying a coating liquid on one surface of the polyester film stretched in the first direction before stretching in the second direction and then stretching the resultant in the second direction (so-called inline coating). Due to the biaxial stretching carried out in the state in which the undercoat layer is formed on the uniaxially stretched polyester film, the adhesion of the formed undercoat layer to the polyester film can be increased.

In a case where undercoat layers are provided on both surfaces of the biaxially stretched polyester film, the undercoat layers may be the same or different from each other in thickness, composition, and the like.

For example, the undercoat layer includes an acrylic resin as a resin component, and may include another resin instead of a portion of the acrylic resin. In addition, various additives may further be included in the undercoat layer as necessary.

As the acrylic resin, for example, polymers including polymethyl methacrylate, polyethyl acrylate, or the like are preferable. As the acrylic resin, a commercially available product which is released may be used. Examples thereof include AS-563A (manufactured by Daicel FineChem Ltd.), JURYMER (registered trademark) ET-410 and JURYMER SEK-301 (both manufactured by Toagosei Co., Ltd.), and BONRON PS-001 and BONRON PS-002 (both manufactured by Mitsui chemicals, Inc.)

As another resin, one or more kinds of polymer selected from polyolefin, polyester, and polyurethane may be employed.

As the olefin-based resin, for example, a modified polyolefin copolymer is preferable. As the polyolefin, a commercially available product which is released may be used. Examples thereof include ELEVES (registered trademark) SE-1013N, SD-1010, TC-4010, and TD-4010 (all manufactured by Unitika Ltd.), HITECH S3148, S3121, and S8512 (all manufactured by TOHO CHEMICAL INDUSTRY Co., Ltd.), and CHEMIPEARL (registered trademark) S-120, S-75N, V100, and EV210H (all manufactured by Mitsui chemicals, Inc.). Among these, it is preferable to use ELEVES (registered trademark) SE-1013N (manufactured by Unitika Ltd.), which is a terpolymer of low-density polyethylene, acrylic acid ester, and maleic anhydride, in terms of adhesiveness improvement.

These polyolefins may be used singly or in a combination of two or more kinds thereof. In a case where of a combination of two or more kinds thereof, a combination of an acrylic resin and a polyolefin, a combination of polyester and a polyolefin, or a combination of a urethane resin and a polyolefin is preferable and a combination of an acrylic resin and a polyolefin is more preferable.

In a case where a combination of an acrylic resin and a polyolefin is used, the content of the acrylic resin with respect to the total amount of the polyolefin and the acrylic resin in the undercoat layer is preferably 25 mass % to 100 mass %, more preferably 50 mass % to 100 mass %, and particularly preferably 75 mass % to 100 mass %.

On the other hand, for example, in a case where an undercoat layer is formed only using a polyolefin without an acrylic resin, the effect of improving the adhesion between the undercoat layer and the second colored layer is insufficient even in a case where the undercoat layer is formed by an inline coating method.

Polyester (for example, VYLONAL (registered trademark) MD-1245 (manufactured by Toyobo Co., Ltd.) may be preferably used in combination with the polyolefin. In addition, it is preferable to add polyurethane to the polyolefin. For example, carbonate-based polyurethane is preferable, and for example, SUPERFLEX (registered trademark) 460 (manufactured by DKS Co. Ltd.) may be preferably used.

As the polyester, for example, polyethylene terephthalate (PET), polyethylene-2,6-naphthalate (PEN), and the like are preferable. As the polyester, for example, a commercially available product which is released may be used. For example, VYLONAL (registered trademark) MD-1245 (manufactured by Toyobo Co., Ltd.) may be preferably used.

As the polyurethane, for example, a carbonate-based urethane resin is preferable, and for example, SUPERFLEX (registered trademark) 460 (manufactured by DKS Co. Ltd.) may be preferably used.

As the crosslinking agent that can be included in the undercoat layer, an epoxy-based crosslinking agent, an isocyanate-based crosslinking agent, a melamine-based crosslinking agent, a carbodiimide-based crosslinking agent, an oxazoline-based crosslinking agent, and the like may be employed. Among these, at least one kind of crosslinking agent selected from a carbodiimide-based crosslinking agent, an oxazoline-based crosslinking agent, and an isocyanate-based crosslinking agent is preferable.

As the crosslinking agent, the crosslinking agent described regarding the first colored layer can also be applied to the undercoat layer.

The thickness of the undercoat layer is not particularly limited, and is preferably in a range of 10 nm to 1000 nm, more preferably in a range of 10 nm to 500 nm, and even more preferably in a range of 100 nm to 500 nm.

<Tint>

From the viewpoint of designability, it is preferable that the solar cell rear surface protective sheet exhibits blue tint as viewed from the first colored layer side. Specifically, in the L*a*b* color system, the L* value, the a* value, and the b* value on the first colored layer side respectively satisfy L*≤40, −3.0≤a*≤3.0, and −20.0≤b*≤0.0, it is preferable that the second colored layer is black, and it is more preferable that L*≤25, −2.0<≤a*<2.0, and −15.0<b*<−5.0 are satisfied.

Here, the L* value, the a* value, and the b* value are values measured by placing black paper on the opposite side of the surface of the solar cell rear surface protective sheet to be measured (the second colored layer side).

In addition, since the second colored layer is black, in a case where the solar cell rear surface protective sheet is observed from the first colored layer side, light from the rear surface side can be blocked by the black second colored layer. Therefore, for example, in a case where a blue first colored layer is formed from the viewpoint of designability, a change in the blue color of the first colored layer caused by the light from the second colored layer side (atmosphere side) is suppressed. Therefore, the solar cell rear surface protective sheet having excellent designability in the above ranges in the L*a*b* color system can be achieved.

Furthermore, since the second colored layer is black, the content of the pigment in the first colored layer can be suppressed to be low. As a result, the adhesiveness between the first colored layer and another layer (the resin base material, the sealing material, and the like) can be improved.

[Production Method of Solar Cell Rear Surface Protective Sheet]

A method of producing the solar cell rear surface protective sheet of this embodiment is not particularly limited.

For example, an un-stretched polyester film formed by melt extrusion is stretched in the first direction, an undercoat layer is formed on one surface or both surfaces of the polyester film through application as necessary, and the polyester film is thereafter stretched in the second direction perpendicular to the first direction.

Next, a second colored layer forming coating liquid including a binder and a colorant is applied onto one surfaces of the polyester film or on the undercoat layer formed as necessary, and the resultant is dried, thereby forming the second colored layer in which each of the average transmittance and the average reflectivity for infrared radiation with a wavelength of 750 nm to 2500 nm is 10% or lower.

On the other hand, an undercoat layer is formed on the other surface side of the polyester film as necessary, a first colored layer forming coating liquid including a binder and a colorant is thereafter applied, and the resultant is dried, thereby forming the first colored layer which has an average transmittance of 20% or higher for infrared radiation with a wavelength of 750 nm to 2500 nm, and has a transmittance of 1% or lower for ultraviolet radiation with a wavelength of 325 nm.

Furthermore, the overcoat layer is formed on the first colored layer as necessary.

The order in which the first colored layer and the second colored layer are formed is not limited, and after the first colored layer is formed on one surface side of the resin base material such as the polyester film, the second colored layer may be formed on the other surface side thereof.

[Solar Cell Module]

The solar cell module of this embodiment includes the solar cell element, the sealing material sealing the solar cell element, the transparent front substrate which is adhered to the sealing material of the solar cell element on a light receiving surface side and is disposed at the outermost surface, and the solar cell rear surface protective sheet in which the first colored layer side of the solar cell rear surface protective sheet of this embodiment described above is adhered to the sealing material of the solar cell element on the opposite side to the light receiving surface side. The solar cell rear surface protective sheet in the solar cell module of this embodiment has excellent weather resistance, and the first colored layer positioned on the sealing material side is prevented from being heated. Therefore, in the solar cell module of this embodiment, a decrease in the power generation efficiency due to an increase in the temperature of the solar cell element is suppressed, and stable power generation performance can be exhibited for a long period of time.

The solar cell rear surface protective sheet of this embodiment is suitable for the production of the solar cell module.

For example, the solar cell module is configured by disposing the solar cell element for converting the light energy of sunlight into electrical energy between the transparent front substrate on which sunlight is incident and the solar cell rear surface protective sheet of the present invention described above and sealing the space between the front substrate and the protective sheet with the sealing material such as an ethylene-vinyl acetate copolymer (EVA; the same applies hereinafter).

Members other than the solar cell module, the solar cell, and the back sheet are described in detail, for example, in “Solar Power System Constitutive Materials” (edited by EIICHI SUGIMOTO and published by KOGYO CHOSAKAI PUBLISHING in 2008).

The transparent front substrate may have a light-transmitting property so as to be capable of transmitting sunlight and may be appropriately selected from substrates that transmit light. From the viewpoint of power generation efficiency, it is preferable that the light transmittance of the front substrate is as high as possible, and as the substrate with high transmittance, for example, a glass substrate and a transparent resin substrate such as an acrylic resin may be suitably used.

Examples of the solar cell element include a variety of well-known solar cell elements such as a solar cell element based on silicon such as monocrystalline silicon, polycrystalline silicon, or amorphous silicon, or a solar cell element based on a III-V group or II-VI group compound semiconductor such as copper-indium-gallium-selenium, copper-indium-selenium, cadmium-tellurium, and gallium-arsenic.

### EXAMPLES

Hereinafter, the present invention will be described in detail using examples, but the present invention is not limited to the following examples without departing from the gist of the present invention. In addition, unless otherwise defined, “parts” is based on mass.

### Example 1

<Production of PET Base Material Film>

—Synthesis of Polyester—

100 kg of high-purity terephthalic acid (manufactured by Mitsui Chemicals, Inc.) and 45 kg of a slurry of ethylene glycol (manufactured by Nippon Shokubai Co., Ltd.) were sequentially supplied for four hours to an esterification reactor which was charged with about 123 kg of bis(hydroxyethyl)terephthalate and was held at a temperature of 250° C. and a pressure of 1.2×10⁵ Pa, and were further subjected to an esterification reaction for one hour after the end of the supply. Thereafter, 123 kg of the obtained esterification reaction product was transported to a polycondensation reactor.

Subsequently, 0.3 mass % of ethylene glycol with respect to the obtained polymer was further added to the polycondensation reactor to which the esterification reaction product was transported. After five minutes of stirring, an ethylene glycol solution of cobalt acetate and an ethylene glycol solution of manganese acetate were added to the obtained polymer so as to reach 30 ppm (cobalt element-equivalent value) and 15 ppm (manganese element-equivalent value), respectively. Furthermore, after five minutes of stirring, a 2 mass % ethylene glycol solution of a titanium alkoxide compound was added to the obtained polymer so as to reach 5 ppm (titanium element-equivalent value). After five minutes, a 10 mass % ethylene glycol solution of ethyl diethylphosphonoacetate was added to the obtained polymer so as to reach 5 ppm. Thereafter, while stirring a low polymer at 30 rpm, the reaction system was gradually increased in temperature from 250° C. to 285° C. and was decreased in pressure to 40 Pa. The period of time until the final temperature was reached and the period of time until the final pressure was reached were both set to 60 minutes.

At a time point at which a predetermined stirring torque was reached, the reaction system was purged with nitrogen, the pressure was returned to normal pressure, and the polycondensation reaction was stopped.

In addition, the resultant was discharged to cold water in a strand shape, was immediately cut into polymer pellets (with a diameter of about 3 mm and a length of about 7 mm).

The period of time until the predetermined stirring torque was reached after the start of depressurization was 3 hours.

As the titanium alkoxide compound, the titanium alkoxide compound (Ti content=4.44 mass %) synthesized in Example 1 of paragraph [0083] of JP2005-340616A was used.

—Solid-Phase Polymerization—

The pellets obtained as above were held at a temperature of 220° C. for 30 hours in a vacuum container held at 40 Pa, thereby causing solid-phase polymerization.

—Production of PET Base Material Film—

The pellets which had been subjected to the solid-phase polymerization as described above were melted and kneaded by a melt extruder at a set temperature of 280° C. and were cast on a metallic drum, thereby producing an un-stretched polyethylene terephthalate sheet (un-stretched PET sheet) having a thickness of approximately 3 mm.

Thereafter, the un-stretched PET film was stretched 3.4 times in the longitudinal direction (machine direction (MD)) at 90° C. (MD stretching).

After the MD stretching, before stretching the resultant in the transverse direction (TD) perpendicular to the MD direction, an undercoat layer forming coating liquid 1 and an undercoat layer forming coating liquid 2 described below were respectively applied onto the first colored layer side and the second colored layer side so that the amount of each of the undercoat layer forming coating liquid 1 and the undercoat layer forming coating liquid 2 applied to the PET sheet after the MD stretching reached 5.1 ml/m², thereby forming each of an undercoat layer 1 and an undercoat layer 2.

<Composition of Undercoat Layer Forming Coating Liquid 1>

Water dispersion liquid of acrylic resin 0.3 parts by mass

[AS-563A, manufactured by Daicel FineChem Ltd., a latex in a solid content of 28 mass %]

Water-soluble oxazoline-based crosslinking agent 0.85 parts by mass

[EPOCROS (registered trademark) WS-700 manufactured by Nippon Shokubai Co., Ltd., solid content 25 mass %]

Distilled water 100 parts by mass

(Composition of Undercoat Layer Forming Coating Liquid 2)

Water dispersion liquid of acrylic resin 0.3 parts by mass

[BONRON (registered trademark) PS-002 manufactured by Mitsui chemicals, Inc., solid content 45.0 mass %]

Water-soluble oxazoline-based crosslinking agent 0.85 parts by mass

[EPOCROS (registered trademark) WS-700 manufactured by Nippon Shokubai Co., Ltd., solid content 25 mass %]

Distilled water 100 parts by mass

Next, the PET sheet in which the undercoat layer was formed was stretched 4.5 times in TD direction at 105° C. (TD stretching). The thickness of the undercoat layer after the TD stretching (thickness after drying) was 80 nm.

Thereafter, the film surface of the resultant was subjected to a heat treatment at 200° C. for 15 seconds. Furthermore, the resultant was subjected to thermal relaxation at 190° C. in the MD and TD directions at an MD relaxation ratio of 5% and a TD relaxation ratio of 5% and a TD relaxation ratio of 11%.

In this manner, a 250 μm-thick biaxially stretched polyethylene terephthalate base material film (hereinafter, referred to as “PET base material film”) was obtained.

<Production of Solar Cell Back Sheet>

A solar cell back sheet was produced by using the PET base material film obtained as described above and forming the first colored layer and the overcoat layer on the undercoat layer 1 side of the PET base material film and forming the second colored layer on the opposite side (the undercoat layer 2 side).

—Formation of Second Colored Layer—

(1) Preparation of Titanium Oxide Dispersion

A titanium oxide dispersion liquid in which the average primary particle diameter of titanium oxide was 0.42 μm was prepared by dispersing titanium oxide using a Dyno-Mill disperser. The average primary particle diameter of the titanium oxide was measured using MICROTRAC MT3300EXII (manufactured by Nikkiso Co., Ltd.)

<Composition of Titanium Oxide Dispersion Liquid>

Titanium oxide 455.8 parts by mass

(White pigment (scattering particles); average primary particle diameter: 0.42 μm, TIPAQUE (registered trademark) CR-95, manufactured by Ishihara Sangyo Kaisha, Ltd., powder)

Polyvinyl alcohol aqueous solution 227.9 parts by mass

(PVA-105, manufactured by Kuraray Co., Ltd., solid content 10 mass %)

Surfactant 5.5 parts by mass

(DEMOL (registered trademark) EP, manufactured by Kao Corporation, solid content 25 mass %)

Distilled water 310.8 parts by mass

(2) Preparation of Second Colored Layer Forming Coating Liquid

Individual components in the composition described below were mixed together, thereby preparing a second colored layer forming coating liquid.

<Composition of Second Colored Layer Forming Coating Liquid>

Titanium oxide dispersion liquid 272 parts by mass

Carbon black dispersion liquid 76 parts by mass

(MF BLACK 5630 (registered trademark), solid content 31.5 mass %, manufactured by Dainichiseika Color & Chemicals Mfg. Co., Ltd.)

Silicone/acrylic composite resin (acrylic resin) 364 parts by mass

(CERANATE (registered trademark) WSA1070, manufactured by DIC Corporation)

Surfactant 20 parts by mass

(1 mass % aqueous solution of NAROACTY (registered trademark) CL-95, manufactured by Sanyo Chemical Industries, Ltd.)

Crosslinking agent (oxazoline-based compound) 112 parts by mass

(EPOCROS (registered trademark) WS-700, solid content 40 mass %, manufactured by Nippon Shokubai Co., Ltd.)

Ammonium diphosphate 29 parts by mass

(ammonium diphosphate as a food additive, manufactured by Nippon Chemical Industrial CO., LTD., 35 mass % aqueous solution)

Distilled water in an amount that causes the total coating liquid to be 1000 parts by mass

(3) Formation of Second Colored Layer

The obtained second colored layer forming coating liquid was applied onto the undercoat layer of the PET base material film so that the amount of titanium oxide applied reached 4 g/m², and the resultant was dried at 170° C. for two minutes, thereby forming a 6 μm-thick second colored layer.

<Formation of EVA Side Easy-Adhesion Layer>

—Preparation of Blue First Colored Layer Forming Coating Liquid—

Components in the composition described below were mixed together, thereby preparing a first colored layer forming coating liquid.

(Composition of First Colored Layer Forming Coating Liquid)

Titanium oxide dispersion liquid obtained as above 76 parts by mass

Carbon black dispersion liquid 17 parts by mass

(MF BLACK 5630 (registered trademark), solid content 31.5 mass %, manufactured by Dainichiseika Color & Chemicals Mfg. Co., Ltd.)

Phthalocyanine blue (copper phthalocyanine) pigment dispersion liquid 21 parts by mass

(EP 700 Blue GA, manufactured by Dainichiseika Color & Chemicals Mfg. Co., Ltd., solid content: 35 mass %,)

Quinacridone red pigment dispersion liquid 38 parts by mass

(NAF 1032, manufactured by Dainichiseika Color & Chemicals Mfg. Co., Ltd., solid content: 45 mass %,)

Water dispersion liquid of polyolefin resin 406 parts by mass

(ELEVES (registered trademark) SE-1013N manufactured by Unitika Ltd., solid content: 20.2 mass %)

Water dispersion liquid of acrylic resin 78 parts by mass

(AS-563A, manufactured by Daicel FineChem Ltd., a latex in a solid content of 28 mass %)

Water-soluble oxazoline compound 208 parts by mass

(EPOCROS (registered trademark) WS700 manufactured by Nippon Shokubai Co., Ltd., solid content: 25 mass %)

Fluorine-based surfactant 5 parts by mass

(sodium=bis(3,3,4,4,5,5,6,6-nonafluoro)=2-sulfonite oxysuccinate, manufactured by FUJIFILM Finechemicals Co. Ltd., concentration 2 mass %)

Ammonium diphosphate 5 parts by mass

(ammonium diphosphate as a food additive, manufactured by Nippon Chemical Industrial CO., LTD., 35 mass % aqueous solution)

Distilled water in an amount that causes the total coating liquid to be 1000 parts by mass

—Preparation of Overcoat Layer Forming Coating Liquid—

Components in the composition described below were mixed together, thereby preparing an overcoat layer forming coating liquid.

(Composition of Overcoat Layer Forming Coating Liquid)

Polyolefin resin 422 parts by mass

(ELEVES (registered trademark) SE-1013N manufactured by Unitika Ltd.)

Water-soluble oxazoline compound 87 parts by mass

(EPOCROS (registered trademark) WS-700 manufactured by Nippon Shokubai Co., Ltd., solid content: 25 mass %)

Fluorine-based surfactant 5 parts by mass

(sodium=bis(3,3,4,4,5,5,6,6-nonafluoro)=2-sulfonite oxysuccinate, manufactured by FUJIFILM Finechemicals Co. Ltd., concentration 2 mass %)

Nonionic surfactant 4 parts by mass

(NAROACTY (registered trademark) CL95, manufactured by Sanyo Chemical Industries, ltd., aqueous solution in a solid content of 1 mass %)

Distilled water in an amount that causes the total coating liquid to be 1000 parts by mass

—Formation of First Colored Layer and Overcoat Layer—

The solar cell back sheet in which the black second colored layer was formed was transported at a transport speed of 80 m/min, and a corona discharge treatment was carried out on the opposite side of the second colored layer formation surface of the PET base material film in the solar cell back sheet under the condition of 730 J/m². Thereafter, the first colored layer forming coating liquid was applied by a bar coating method so that the amount of applied titanium oxide, which is one of coloring pigments, reached 1.5 g/m², thereby forming a coating film. The coating film was dried at 170° C. for two minutes, thereby forming a first colored layer.

Next, the overcoat layer forming coating liquid was applied onto the first colored layer by a bar coating method so that the application amount reached 0.5 g/m², thereby forming a coating film. The coating film was dried at 170° C. for two minutes, thereby forming an overcoat layer.

Accordingly, the blue solar cell back sheet in which an EVA side easy-adhesion layer with the blue first colored layer (a layer of the olefin-acrylic composite resin) having a dry thickness of 6 μm and the overcoat layer (a layer of the olefin-based resin) having a dry thickness of 0.5 μm laminated in this order is provided on the opposite side of the second colored layer formation surface of the PET base material film in the solar cell back sheet was obtained.

<Production of Solar Cell Module>

A solar cell sheet glass (Sunplus SM manufactured by Nippon Sheet Glass Co., Ltd.) having a thickness of 3.2 mm as the front substrate to serve as a light receiving surface, a light receiving surface side sealing material (manufactured by Shenzhen Sveck Technology Co, Ltd., ethylene-vinyl acetate copolymer (EVA) SVK-15297), a crystalline solar cell element (Q6LMX3 manufactured by Hanwha Q CELLS), a rear surface side sealing material (EVA F806 manufactured by Hangzhou First PV Material Co., Ltd.), and the solar cell back sheet produced as described above were superimposed in this order to form a laminate. At this time, the solar cell back sheet was disposed so that the overcoat layer was in contact with the rear surface side sealing material.

The laminate was laminated to cause the individual members to be adhered using a vacuum laminator (vacuum laminator LAMINATOR 05055 manufactured by Nisshinbo Mechatronics Inc.) under conditions with a temperature of 145° C., evacuation for 5 minutes, and pressurization for 10 minutes, thereby producing a solar cell module.

### Examples 2 to 12, Comparative Examples 1 to 5

<Production of Solar Cell Back Sheet>

Solar cell back sheets of Examples 2 to 12 and Comparative Examples 1 to 5 were produced in the same manner as in Example 1 except that the kind and content of the colorants included in the first colored layer and the second colored layer during the production of the solar cell back sheet of Example 1 were changed as shown in Table 1.

<Production Solar Cell Module>

Solar cell modules were produced in the same manner as in Example 1 except that solar cell back sheets produced in the corresponding examples were used as the solar cell back sheets during the production of the solar cell module of Example 1.

[Evaluation]

The following evaluations were carried out on the solar cell back sheet (hereinafter, sometimes referred to as “sheet”) and the solar cell module (hereinafter, sometimes referred to as “module”) obtained in each of the examples as described above.

<1> Power Generation Efficiency (Cell Temperature)

A thermocouple was installed between the solar cell and the EVA at the time of production of the module so that the cell temperature can be measured. The temperature in a case where light corresponding to AM1.5G (standard solar spectrum) was irradiated using a solar simulator for six hours was measured. It can be said that as the cell temperature decreases, the decrease in the power generation efficiency is suppressed. The evaluation standard is as follows.

A: 60° C. or lower

B: higher than 60° C. and lower than 85° C.

C: 85° C. or higher

<2> Sheet Weather Resistance

After the production of the module, ultraviolet radiation was irradiated from the front substrate side in an environment with a temperature of 63° C. and a relative humidity of 50% at an irradiance of 90 mW/cm² for 200 hours using EYE Super UV Tester SUV-W161 (manufactured by Iwasaki Electric Co., Ltd.). Thereafter, the module was re-heated to 145° C., and the sheet was peeled off from the EVA and was adjusted in humidity for 24 hours under conditions with a temperature of 23° C. and a relative humidity of 50%. Thereafter, the elastic modulus thereof was measured by a tensile tester (TENSILON manufactured by A&D Company) and was compared to the elastic modulus of the sheet before being irradiated with the infrared radiation.

Specifically, the elastic modulus retention rate was calculated by (sheet elastic modulus after ultraviolet irradiation/sheet elastic modulus before ultraviolet irradiation)×100%, and it can be said that the higher the elastic modulus retention rate, the higher the weather resistance. The evaluation standard is as follows.

A: The elastic modulus retention rate is 80% or higher.

B: The elastic modulus retention rate is 50% or higher and lower than 80%.

C: The elastic modulus retention rate is lower than 50%.

<3> Pigment Weather Resistance

After the production of the module, ultraviolet radiation was irradiated from the front substrate side in an environment with a temperature of 63° C. and a relative humidity of 50% at an irradiance of 90 mW/cm² for 200 hours using EYE Super UV Tester SUV-W161 (manufactured by Iwasaki Electric Co., Ltd.). Thereafter, the module was re-heated to 145° C., the sheet was peeled off from the EVA, and the tint of the EVA surface side (the first colored layer side) was measured. Tint measurement was carried out by placing black paper on the opposite side (the second colored layer side) of the surface of the sheet to be measured, using a spectrocolorimeter CM-700D (manufactured by Konica Minolta Japan, Inc.). Evaluation was carried out by SCE (specular component excluded) measurement values in a case where a D50 light source is used. The evaluation standard is as follow.

A: Δa*≤1.5, and Δb*≤5.0

B: Δa*≤3.0, and Δb*≤10.0

C: Δa*>3.0, or Δb*>10.0

<4> Designability (Tint)

Tint measurement was carried out by placing black paper on the opposite side (the second colored layer side) of the surface of the sheet to be measured, using the spectrocolorimeter CM-700D (manufactured by Konica Minolta Japan, Inc.). Evaluation was carried out by SCE (specular component excluded) measurement values in a case where a D50 light source issued. The evaluation standard is as follow.

A: L*≤25, −2.0<a*<2.0, −15.0<b*<−5.0

B: L*≤40, −3.0≤a*≤3.0, −20.0≤b*≤0.0

C: Outside the range of B

<5> Adhesiveness

The solar cell back sheet obtained in each of the examples was cut into 1.0 cm (TD direction)×30 cm (MD direction) (the MD and TD directions are stretching directions of the PET base material film). Next, two EVA films (Hangzhou, F806) were laminated on a glass plate having a size of 20 cm×20 cm×0.3 cm in thickness.

At a distance of 10 cm to 20 cm from one end portion of the glass plate on which the EVA films were laminated, a polyethylene terephthalate (PET) film (CERAPEEL (registered trademark) manufactured by Toray Industries, Inc.) treated with a release agent was laminated, the other end portion and an end portion in the MD direction of the solar cell back sheet were aligned with each other and the solar cell back sheet was placed so as to cause the overcoat layer to come into contact with the EVA film, and the resultant was laminated using the vacuum laminator (LAMINATOR 0505S) manufactured by Nisshinbo Mechatronics Inc. under conditions with a temperature of 145° C., evacuation for 4 minutes, and pressurization for 10 minutes.

The laminated sample was tested for 48 hours under conditions with a temperature of 105° C. and a relative humidity of 100%, and thereafter the solar cell back sheet adhered to the EVA was adjusted in humidity for 24 or more hours under conditions with a temperature of 23° C. and a relative humidity of 50%. A portion with a width of 1.0 cm in the sample produced above was pulled at 180° by the tensile tester (TENSILON manufactured by A&D Company) at a speed of 100 mm/min. Then, the fracture stress was evaluated according to the following evaluation standard. A higher fracture stress indicates higher cohesive fracture resistance, that is, adhesiveness, in the evaluation.

A: 3 N/mm or higher

B: higher than 1 N/mm and lower than 3 N/mm

C: 1 N/mm or lower

<6> Infrared and Ultraviolet Transmittance

Light at 750 nm to 2500 nm (infrared measurement) or at 300 nm to 400 nm (ultraviolet measurement) was caused to be incident on the measurement surface of the sheet by a spectrophotometer V670 (manufactured by JASCO Corporation), and the transmittance of the colored layers for each of infrared radiation and ultraviolet radiation was measured. In addition, the measurement of the infrared and ultraviolet transmittance was carried out in a state in which the colored layer other than a measurement object was peeled off.

—Calculation Method of Average Transmittance of Infrared Radiation—

The transmittance of the first colored layer or the second colored layer was measured every 5 nm from 750 nm to 2500 nm, and the average transmittance was calculated by the arithmetic mean.

—Measurement Method of Ultraviolet Transmittance—

The transmittance of the first colored layer for ultraviolet radiation at 325 nm was measured.

<7> Infrared Reflectivity

Light at 750 nm to 2500 nm was caused to be incident on the measurement surface of the sheet by a spectrophotometer UV3100 (manufactured by Shimadzu Corporation), and the infrared reflectivity of the second colored layer was measured. In addition, the measurement of the infrared reflectivity of the second colored layer was carried out in a state in which the first colored layer was peeled off.

—Calculation Method of Average Reflectivity of Infrared Radiation—

The reflectivity was measured every 5 nm from 750 nm to 2500 nm, and the average reflectivity was calculated by the arithmetic mean.

The kinds and contents of the colorants included in the first colored layer and the second colored layer and the evaluation results are shown in Table 1 below.

In Table 1, a pigment 1 is red, a pigment 2 is blue, pigments 3 and 5 are black, and pigments 4 and 6 are white. The pigments in Table 1 are as follows.

Iron oxide: MF 5160 Brown (manufactured by Dainichiseika Color & Chemicals Mfg. Co., Ltd.)

Dioxazine violet: EP-1500 Violet 3RN (manufactured by Dainichiseika Color & Chemicals Mfg. Co., Ltd.)

Perylene red: AQYLA Perylene Red (manufactured by Kusakabe Corporation)

Naphthol AS: EP-720 Red 2B (manufactured by Dainichiseika Color & Chemicals Mfg. Co., Ltd.)

TABLE 1

| | Pigments in colored layers of solar cell back sheet | | | | | | | | |
|---|---|---|---|---|---|---|---|---|---|
| | First colored layer (solar cell side) | | | | | | | | |
| | | | | | | | | | Pigment |
| | Pigment 1 | | Pigment 2 | | Pigment 3 | | Pigment 4 | | volume |
| | Kind | Proportion | Kind | Proportion | Kind | Proportion | Kind | Proportion | fraction |
| | — | mass % | — | mass % | — | mass % | — | mass % | vol % |
| Example 1 | Quinacridone | 7.6 | Copper | 3.3 | Carbon | 2.4 | Titanium | 17.5 | 16.1 |
| | red | | phthalocyanine | | black | | oxide | | |
| Example 2 | Quinacridone | 8.4 | Copper | 3.6 | Carbon | 3.6 | Titanium | 19.3 | 19 |
| | red | | phthalocyanine | | black | | oxide | | |
| Example 3 | Quinacridone | 24.8 | Copper | 10.8 | Carbon | 2.4 | Titanium | 17.5 | 40 |
| | red | | phthalocyanine | | black | | oxide | | |
| Example 4 | Quinacridone | 7.6 | Copper | 3.3 | Carbon | 2.4 | Titanium | 17.5 | 16.1 |
| | red | | phthalocyanine | | black | | oxide | | |
| Example 5 | Quinacridone | 7.6 | Copper | 3.3 | Carbon | 2.4 | Titanium | 13.1 | 14.2 |
| | red | | phthalocyanine | | black | | oxide | | |
| Example 6 | Quinacridone | 7.6 | Copper | 3.3 | Carbon | 2.4 | Titanium | 17.5 | 16.1 |
| | red | | phthalocyanine | | black | | oxide | | |
| Example 7 | Iron oxide | 22.8 | Copper | 3.3 | Carbon | 2.4 | Titanium | 17.5 | 22.6 |
| | | | phthalocyanine | | black | | oxide | | |
| Example 8 | Dioxazine | 7.6 | Copper | 2.2 | Carbon | 2.4 | Titanium | 17.5 | 12.4 |
| | violet | | phthalocyanine | | black | | oxide | | |
| Example 9 | Perylene red | 7.6 | Copper | 2.2 | Carbon | 2.4 | Titanium | 17.5 | 12.4 |
| | | | phthalocyanine | | black | | oxide | | |
| Example 10 | Quinacridone | 1.9 | Copper | 0.8 | Carbon | 0.6 | Titanium | 17.5 | 7.7 |
| | red | | phthalocyanine | | black | | oxide | | |
| Example 11 | Naphthol AS | 7.6 | Copper | 3.3 | Carbon | 2.4 | Titanium | 17.5 | 16.1 |
| | | | phthalocyanine | | black | | oxide | | |
| Example 12 | Quinacridone | 29.4 | Copper | 11.6 | Carbon | 2.4 | Titanium | 17.5 | 46 |
| | red | | phthalocyanine | | black | | oxide | | |
| Comparative | Quinacridone | 11.4 | Copper | 4.8 | Carbon | 3.6 | Titanium | 17.5 | 21.9 |
| Example 1 | red | | phthalocyanine | | black | | oxide | | |
| Comparative | — | 0 | — | 0 | — | 0 | — | 0 | — |
| Example 2 | | | | | | | | | |
| Comparative | Quinacridone | 7.6 | Copper | 3.3 | Carbon | 2.4 | Titanium | 17.5 | 16.1 |
| Example 3 | red | | phthalocyanine | | black | | oxide | | |
| Comparative | Quinacridone | 7.6 | Copper | 3.3 | Carbon | 2.4 | Titanium | 17.5 | 16.1 |
| Example 4 | red | | phthalocyanine | | black | | oxide | | |
| Comparative | Quinacridone | 7.6 | Copper | 3.3 | Carbon | 2.4 | Titanium | 0.8 | 9.5 |
| Example 5 | red | | phthalocyanine | | black | | oxide | | |

| | Pigments in colored layers of | | | | | | | | | |
|---|---|---|---|---|---|---|---|---|---|---|
| | solar cell back sheet | | | | Evaluation | | | | | |
| | Second colored layer (atmosphere side) | | | | First colored layer (solar cell side) | | | | | |
| | Pigment 5 | | Pigment 6 | | <6> | <6> | <4> | | | |
| | Kind | Proportion | Kind | Proportion | Infrared | Ultraviolet | Tint | | | |
| | — | mass % | — | mass % | transmittance | transmittance | L* | a* | b* | Designability |
| Example 1 | Carbon | 7.2 | Titanium | 37.8 | 26% | <1% | 18 | 0.3 | −10.5 | A |
| | black | | oxide | | | | | | | |
| Example 2 | Carbon | 7.2 | Titanium | 37.8 | 20% | <1% | 15 | 0.3 | −11.1 | A |
| | black | | oxide | | | | | | | |
| Example 3 | Carbon | 7.2 | Titanium | 37.8 | 25% | <1% | 12 | 0.1 | −9.9 | A |
| | black | | oxide | | | | | | | |
| Example 4 | Carbon | 5.8 | Titanium | 30.2 | 26% | <1% | 18 | 0.3 | −10.5 | A |
| | black | | oxide | | | | | | | |
| Example 5 | Carbon | 7.2 | Titanium | 37.8 | 29% | 1.0% | 15 | 0.2 | −10.7 | A |
| | black | | oxide | | | | | | | |
| Example 6 | Carbon | 7.2 | Titanium | 37.8 | 26% | <1% | 17 | 0.2 | −10.4 | A |
| | black | | oxide | | | | | | | |
| Example 7 | Carbon | 7.2 | Titanium | 37.8 | 21% | <1% | 16 | −1.2 | −6.5 | A |
| | black | | oxide | | | | | | | |
| Example 8 | Carbon | 7.2 | Titanium | 37.8 | 27% | <1% | 19 | 0.8 | −9.8 | A |
| | black | | oxide | | | | | | | |
| Example 9 | Carbon | 7.2 | Titanium | 37.8 | 32% | <1% | 12 | 0.9 | −8.7 | A |
| | black | | oxide | | | | | | | |
| Example 10 | Carbon | 7.2 | Titanium | 37.8 | 45% | <1% | 42 | −0.2 | −10.8 | C |
| | black | | oxide | | | | | | | |
| Example 11 | Carbon | 7.2 | Titanium | 37.8 | 26% | <1% | 18 | 0.3 | −10.5 | A |
| | black | | oxide | | | | | | | |
| Example 12 | Carbon | 7.2 | Titanium | 37.8 | 20% | <1% | 11 | −0.5 | −10.5 | A |
| | black | | oxide | | | | | | | |
| Comparative | Carbon | 7.2 | Titanium | 37.8 | 17% | <1% | 10 | 0.1 | −10.1 | A |
| Example 1 | black | | oxide | | | | | | | |
| Comparative | Carbon | 7.2 | Titanium | 37.8 | 85% | 87% | 35 | 0.1 | 0.3 | C |
| Example 2 | black | | oxide | | | | | | | |
| Comparative | — | 0 | — | 0 | 26% | <1% | 18 | 0.3 | −10.5 | A |
| Example 3 | | | | | | | | | | |
| Comparative | Carbon | 3.6 | Titanium | 37.8 | 26% | <1% | 19 | 0.3 | −10.4 | A |
| Example 4 | black | | oxide | | | | | | | |
| Comparative | Carbon | 7.2 | Titanium | 37.8 | 35% | 2.2% | 10 | 0.1 | −10.6 | A |
| Example 5 | black | | oxide | | | | | | | |

| | Evaluation | | | | | | |
|---|---|---|---|---|---|---|---|
| | First colored layer (solar cell side) | | | | | | |
| | | <3> | Second colored layer (atmosphere side) | | | <2> | <1> |
| | <5> | Pigment | <6> | <7> | | Sheet | Power |
| | Adhesiveness | weather | Infrared | Infrared | | weather | generation |
| | evaluation | resistance | transmittance | reflectivity | Color | resistance | efficiency |
| Example 1 | A | A | 7% | 5% | Black | A | A |
| Example 2 | A | A | 7% | 5% | Black | A | B |
| Example 3 | B | A | 7% | 5% | Black | A | A |
| Example 4 | A | A | 10% | 10% | Black | A | B |
| Example 5 | A | A | 7% | 5% | Black | B | A |
| Example 6 | A | A | 7% | 5% | Black | A | A |
| Example 7 | A | A | 7% | 5% | Black | A | A |
| Example 8 | A | A | 7% | 5% | Black | A | A |
| Example 9 | A | A | 7% | 5% | Black | A | A |
| Example 10 | A | A | 7% | 5% | Black | A | A |
| Example 11 | A | C | 7% | 5% | Black | A | A |
| Example 12 | C | A | 7% | 5% | Black | A | B |
| Comparative | B | A | 7% | 5% | Black | A | C |
| Example 1 | | | | | | | |
| Comparative | A | — | 7% | 5% | Black | C | C |
| Example 2 | | | | | | | |
| Comparative | A | A | 85% | 11% | Colorless | A | C |
| Example 3 | | | | | | | |
| Comparative | A | A | 12% | 18% | Black to | A | C |
| Example 4 | | | | | gray | | |
| Comparative | A | A | 7% | 5% | Black | C | A |
| Example 5 | | | | | | | |

As shown in Table 1, in the examples, both the sheet heat resistance and power generation efficiency are excellent, and the solar cell modules of the examples can exhibit high power generation efficiency for a long period of time. In Example 11 using naphthol AS as the red pigment, it is considered that the resistance to ultraviolet light is low and the pigment weather resistance is low.

On the other hand, in the comparative example, at least one of the sheet heat resistance or power generation efficiency is evaluated as C, and in the solar cell modules of the comparative examples, it is difficult to exhibit high power generation efficiency for a long period of time.

The entirety of the disclosure of Japanese Patent Application No. 2015-166280 filed on Aug. 25, 2015, is incorporated herein by reference.

Publications, patent applications, and technical standards described in this specification are incorporated herein by reference to the same degree as in a case where those publications, patent applications, and technical standards are individually described in detail.

What is claimed is:

1. A solar cell rear surface protective sheet comprising:
a resin base material;
a first colored layer which is disposed on one surface side of the resin base material, has an average transmittance of 20% or higher for infrared radiation with a wavelength of 750 nm to 2500 nm, and has a transmittance of 1% or lower for ultraviolet radiation with a wavelength of 325 nm; and
a second colored layer which is disposed on the other surface side of the resin base material and of which each of an average transmittance and an average reflectivity for infrared radiation with a wavelength of 750 nm to 2500 nm is 10% or lower.

2. The solar cell rear surface protective sheet according to claim 1,
wherein the first colored layer includes a pigment, and
a total volume fraction of the pigment in the first colored layer is 40 vol % or less.

3. The solar cell rear surface protective sheet according to claim 1,
wherein the first colored layer includes a white pigment and at least one kind of pigment selected from a quinacridone-based compound, a phthalocyanine-based compound, a dioxazine-based compound, and a perylene-based compound.

4. The solar cell rear surface protective sheet according to claim 2,
wherein the first colored layer includes a white pigment and at least one kind of pigment selected from a quinacridone-based compound, a phthalocyanine-based compound, a dioxazine-based compound, and a perylene-based compound.

5. The solar cell rear surface protective sheet according to claim 1,
wherein the second colored layer includes carbon black and a white pigment.

6. The solar cell rear surface protective sheet according to claim 4,
wherein the second colored layer includes carbon black and a white pigment.

7. The solar cell rear surface protective sheet according to claim 1,
wherein an L* value, an a* value, and a b* value on the first colored layer side respectively satisfy L*≤40, −3.0≤a*≤3.0, and −20.0 b*≤0.0, and
the second colored layer is black.

8. The solar cell rear surface protective sheet according to claim 6,
wherein an L* value, an a* value, and a b* value on the first colored layer side respectively satisfy L*≤40, −3.0≤a*≤3.0, and −20.0≤b*≤0.0, and
the second colored layer is black.

9. A solar cell module comprising:
a solar cell element;
a sealing material sealing the solar cell element;
a transparent front substrate which is adhered to the sealing material on a light receiving surface side of the solar cell element and is disposed at an outermost surface; and
a solar cell rear surface protective sheet in which a first colored layer side of the solar cell rear surface protective sheet according to claim 1 is adhered to the sealing material on the opposite side to the light receiving surface side of the solar cell element.

10. A solar cell module comprising:
a solar cell element;
a sealing material sealing the solar cell element;
a transparent front substrate which is adhered to the sealing material on a light receiving surface side of the solar cell element and is disposed at an outermost surface; and
a solar cell rear surface protective sheet in which a first colored layer side of the solar cell rear surface protective sheet according to claim 6 is adhered to the sealing material on the opposite side to the light receiving surface side of the solar cell element.

11. A solar cell module comprising:
a solar cell element;
a sealing material sealing the solar cell element;
a transparent front substrate which is adhered to the sealing material on a light receiving surface side of the solar cell element and is disposed at an outermost surface; and
a solar cell rear surface protective sheet in which a first colored layer side of the solar cell rear surface protective sheet according to claim 8 is adhered to the sealing material on the opposite side to the light receiving surface side of the solar cell element.
